(19) United States
(12) Patent Application Publication
(10) Pub. No.: US 2026/0182017 A1
(43) Pub. Date: Jun. 25, 2026

(54) SEMICONDUCTOR DEVICE AND METHOD FOR FABRICATING THE SAME

(71) Applicant: Samsung Electronics Co., Ltd., Suwon-si (KR)

(72) Inventors: Woo Seok PARK, Suwon-si (KR); Je Hyoung KOO, Suwon-si (KR); Yong Hui LEE, Suwon-si (KR)

(21) Appl. No.: 19/424,369

(22) Filed: Dec. 18, 2025

(30) Foreign Application Priority Data
Dec. 23, 2024 (KR) 10-2024-0194380

(51) Int. Cl. H10D 84/85; H10D 84/01

(52) U.S. Cl. CPC H10D 84/852; H10D 84/0167; H10D 84/0188

(57) ABSTRACT

A semiconductor device includes a lower pattern including a first sidewall and a second sidewall, a channel separation structure including a core separation pattern and a liner separation pattern, the liner separation pattern extending along sidewalls of the core separation pattern, a field insulating film contacting the second sidewall of the lower pattern, a channel pattern disposed on the lower pattern, and a source/drain pattern contacting the channel pattern and the channel separation structure. The core separation pattern includes a first portion, a second portion, and a connection portion, the connection portion of the core separation pattern is disposed between the first and second portions of the core separation pattern, and a slope of the sidewall of the core separation pattern at the connection portion is smaller than a slope at the first portion and a slope of the sidewall at the second portion.

### CROSS-REFERENCE TO RELATED APPLICATION

This application claims priority under 35 U.S.C. 119 from Korean Patent Application No. 10-2024-0194380 filed on Dec. 23, 2024, in the Korean Intellectual Property Office, the contents of which are herein incorporated by reference in their entirety.

### BACKGROUND

As one of the scaling techniques for increasing the density of semiconductor devices, multi-gate transistors have been proposed, in which fin-or nanowire-shaped multi-channel active patterns (or silicon bodies) are formed on a substrate, and gates are formed on the surfaces of the multi-channel active patterns.

Since such multi-gate transistors utilize three-dimensional (3D) channels, scaling can be readily achieved. Additionally, the current control capability can be improved without increasing the gate length of the multi-gate transistors. Furthermore, short channel effects (SCE), where channel regions'potential is influenced by drain voltages, can be effectively suppressed.

Meanwhile, as the pitch size of semiconductor devices decreases, research is needed to reduce capacitance between contacts within the semiconductor devices and to ensure electrical stability.

### SUMMARY

Some aspects of the present disclosure provide semiconductor devices that can exhibit improved device performance and/or integration density.

Some aspects of the present disclosure provide methods for fabricating semiconductor device that can exhibit improved device performance and/or integration density.

Further objectives, improvements, and advantages not explicitly stated above will be clearly understood by those skilled in the art based on the following description.

According to some implementations of the present disclosure, there is provided a semiconductor device including a lower pattern including a first sidewall and a second sidewall that extend in a first direction and are opposite to each other in a second direction, a channel separation structure extending in the first direction, contacting the first sidewall of the lower pattern, and including a core separation pattern and a liner separation pattern, the liner separation pattern extending along sidewalls of the core separation pattern, a field insulating film contacting the second sidewall of the lower pattern, a gate structure disposed on the lower pattern, contacting the channel separation structure, and including a gate electrode and a gate insulating film, a channel pattern disposed on the lower pattern and including a plurality of sheet patterns spaced apart in a third direction, each of the sheet patterns being connected to the channel separation structure and a source/drain pattern contacting the channel pattern and the channel separation structure, wherein the core separation pattern includes a first portion, a second portion, and a connection portion, the connection portion of the core separation pattern is disposed between the first and second portions of the core separation pattern, the first portion of the core separation pattern overlaps the lower pattern in the second direction, a slope of the sidewall of the core separation pattern at the connection portion is smaller than a slope of the sidewall of the core separation pattern at the first portion, and the slope of the sidewall of the core separation pattern at the connection portion is smaller than a slope of the sidewall of the core separation pattern at the second portion.

According to some implementations of the present disclosure, there is provided a semiconductor device including a lower pattern including a first sidewall and a second sidewall that extend in a first direction and are opposite to each other in a second direction, a channel separation structure extending in the first direction, contacting the first sidewall of the lower pattern, and including a first core separation pattern, a second core separation pattern, and a liner separation pattern, wherein the liner separation pattern extends along sidewalls of the first core separation pattern, and the second core separation pattern is disposed on the first core separation pattern, a field insulating film contacting the second sidewall of the lower pattern, a gate structure disposed on the lower pattern, contacting the channel separation structure, and including a gate electrode and a gate insulating film, a gate capping pattern disposed on the gate structure and the channel separation structure and contacting an upper surface of the first core separation pattern, wherein an upper surface of the gate capping pattern is disposed on the same plane as an upper surface of the second core separation pattern, a channel pattern disposed on the lower pattern and including a plurality of sheet patterns spaced apart in a third direction, each of the sheet patterns being connected to the channel separation structure and a source/drain pattern contacting the channel pattern and the channel separation structure, wherein the channel separation structure includes a first region in contact with the gate structure and a second region in contact with the source/drain pattern, the first core separation pattern is disposed in both the first and second regions of the channel separation structure, the second core separation pattern is disposed in the second region of the channel separation structure and not in the first region of the channel separation structure, and the first core separation pattern has a “T” shaped cross-section in the first region of the channel separation structure.

According to some implementations of the present disclosure, there is provided a semiconductor device including a lower pattern including a first sidewall and a second sidewall that extend in a first direction and are opposite to each other in a second direction, a channel separation structure extending in the first direction, contacting the first sidewall of the lower pattern, and including a core separation pattern and a liner separation pattern, a field insulating film contacting the second sidewall of the lower pattern, a gate structure disposed on the lower pattern, extending in the second direction, and including a gate electrode and a gate insulating film, the gate insulating film being in contact with the core separation pattern, a channel pattern disposed on the lower pattern and including a plurality of sheet patterns spaced apart in a third direction, each of the sheet patterns being connected to the channel separation structure and a source/drain pattern contacting the channel pattern and sidewalls of the core separation pattern, wherein the liner separation pattern includes a lower liner separation pattern disposed between the sidewalls of the core separation pattern and the first sidewall of the lower pattern and a plurality of connection liner separation patterns spaced apart in the third direction from the lower liner separation pattern, the connection liner separation patterns connect the respective sheet patterns to the core separation pattern, the core separation pattern includes a first portion, a second portion, and a connection portion, the connection portion of the core separation pattern is disposed between the first portion and the second portion of the core separation pattern, the lower liner separation pattern is disposed between the first portion of the core separation pattern and the lower pattern, a slope of the sidewall of the core separation pattern at the connection portion is smaller than a slope of the sidewall of the core separation pattern at the first portion, and the slope of the sidewall of the core separation pattern at the connection portion is smaller than a slope of the sidewall of the core separation pattern at the second portion.

It should be noted that the effects of the present disclosure are not limited to those described above, and other effects of the present disclosure will be apparent from the following description.

### BRIEF DESCRIPTION OF THE DRAWINGS

FIG. 1 is a layout diagram illustrating an example of a semiconductor device.

FIGS. 2 through 5 are cross-sectional views taken along lines A-A, B-B, C-C, and D-D, respectively, of FIG. 1.

FIG. 6 is a diagram illustrating an example of a shape of a first sheet pattern illustrated in FIG. 2.

FIG. 7 is an enlarged view of portion Q of FIG. 4.

FIG. 8 is an enlarged view of portion S of FIG. 5.

FIG. 9 is a plan view illustrating a cut of portion P of FIG. 1 at a first height level.

FIG. 10 is a plan view illustrating a cut of portion P of FIG. 1 at a second height level.

FIG. 11 is a plan view illustrating a cut of portion P of FIG. 1 at a third height level.

FIGS. 12 through 14 are cross-sectional views illustrating examples of semiconductor devices.

FIGS. 15 through 18 are cross-sectional, cross-sectional, plan, and plan views, respectively, illustrating an example of a semiconductor device.

FIGS. 19 and 20 are cross-sectional views illustrating an example of a semiconductor device.

FIGS. 21 through 23 are cross-sectional views illustrating examples of semiconductor devices.

FIGS. 24 and 25 are cross-sectional views illustrating an example of a semiconductor device.

FIGS. 26 and 27 are cross-sectional views illustrating an example of a semiconductor device.

FIGS. 28 and 29 are cross-sectional views illustrating an example of a semiconductor device.

FIGS. 30 through 57 are diagrams illustrating stages of an example of a method for manufacturing a semiconductor device.

### DETAILED DESCRIPTION

Although terms such as first and second are used to describe various elements or components in the present specification, these elements or components are not limited by these terms. These terms are only used to distinguish a single element or component from other elements or components, without implying any required ordering, arrangement, or the like. Therefore, a first element or component referred to below may be a second element or component within the scope of the present disclosure.

The drawings herein illustrate transistors including nanowires or nanosheets as examples, but the scope of the present disclosure is not limited thereto. For example, the descriptions provided herein may also be applied to two-dimensional (2D) material-based field-effect transistors (FETs) and their heterostructures.

Additionally, the semiconductor devices may include, for example, FinFETs with fin-shaped channel regions, tunneling FETs, or three-dimensional (3D) transistors. The semiconductor devices may also include bipolar junction transistors (BJTs) and laterally diffused metal-oxide-semiconductor (LDMOS) transistors.

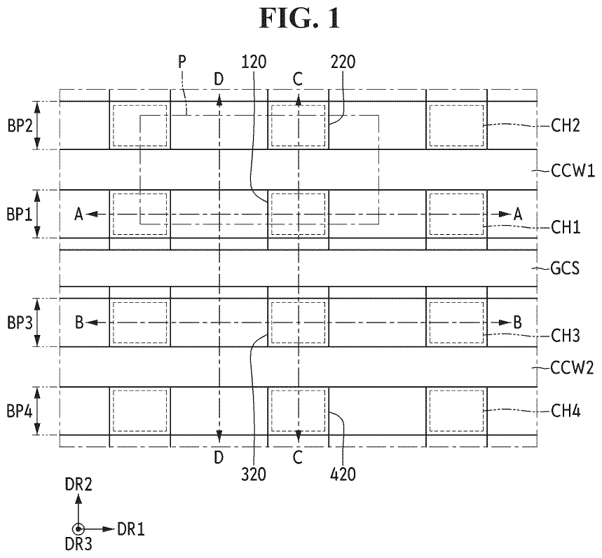

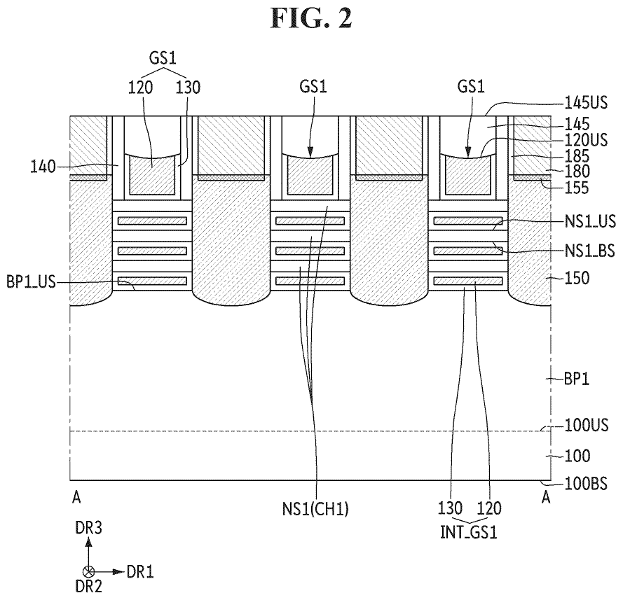

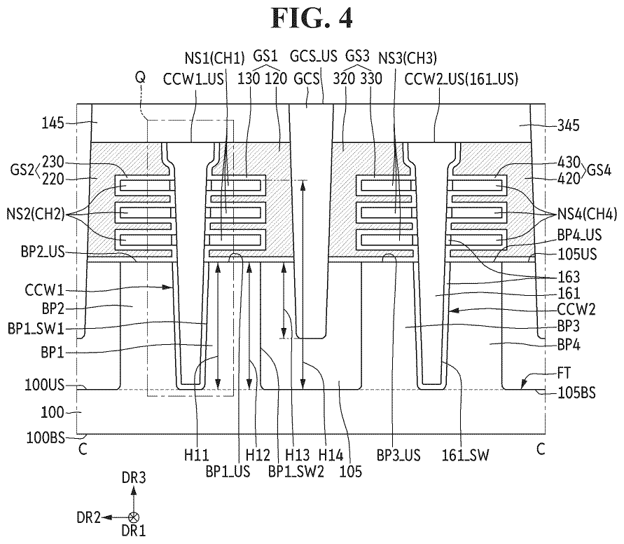

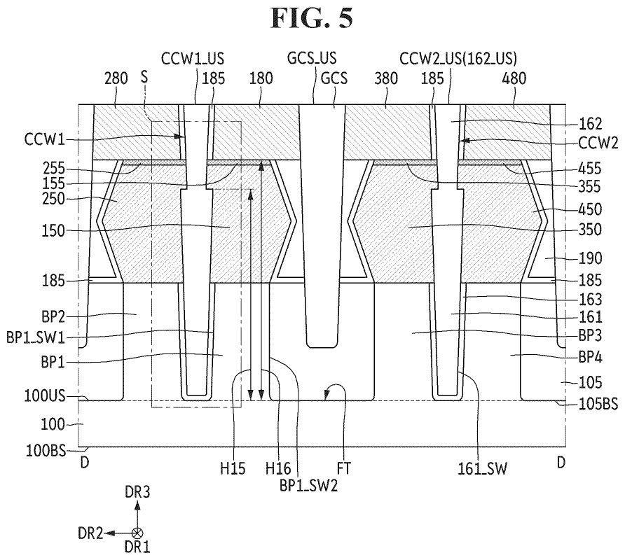

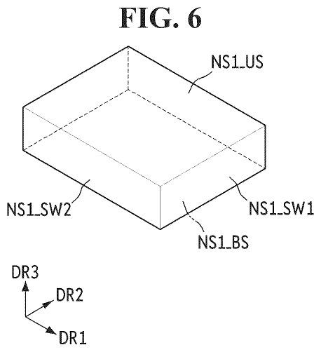

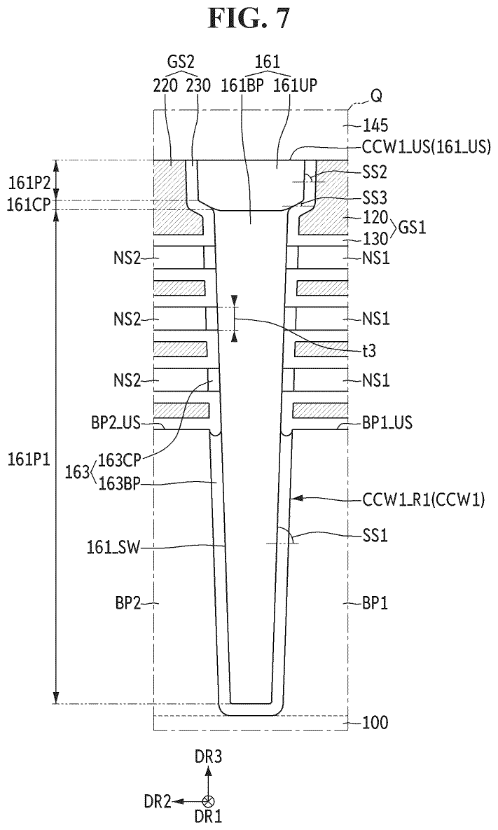

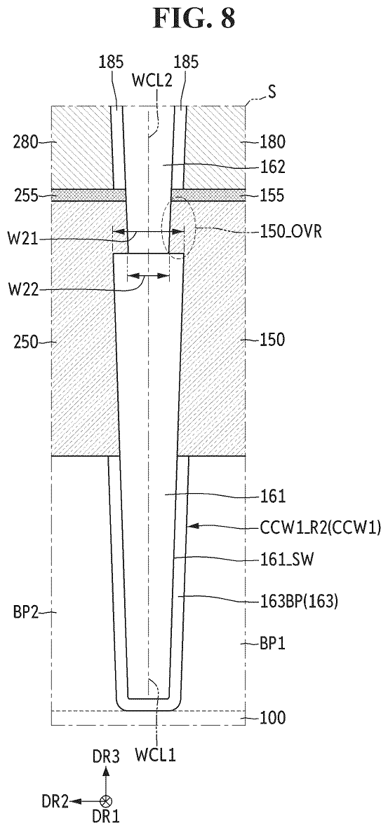

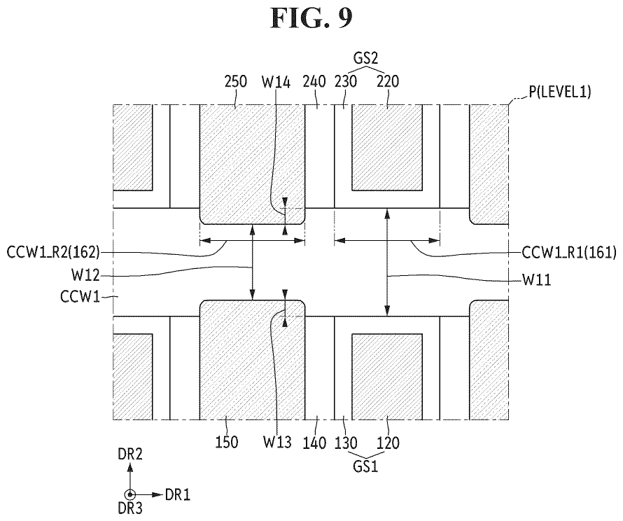

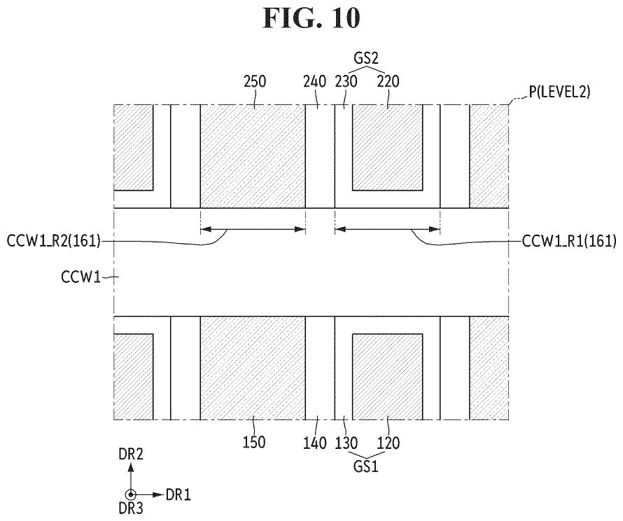

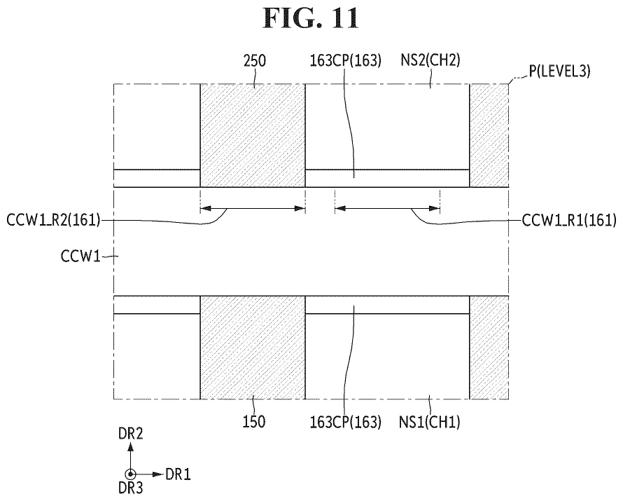

An example of a semiconductor device will hereinafter be described with reference to FIGS. 1 through 11. FIG. 1 is a layout diagram illustrating the semiconductor device. FIGS. 2 through 5 are cross-sectional views taken along lines A-A, B-B, C-C, and D-D, respectively, of FIG. 1. FIG. 6 is a diagram illustrating the shape of a first sheet pattern illustrated in FIG. 2. FIG. 7 is an enlarged view of portion Q of FIG. 4. FIG. 8 is an enlarged view of portion S of FIG. 5. FIG. 9 is a plan view illustrating a cut of portion P of FIG. 1 at a first height level. FIG. 10 is a plan view illustrating a cut of portion P of FIG. 1 at a second height level. FIG. 11 is a plan view illustrating a cut of portion P of FIG. 1 at a third height level.

For reference, FIG. 1 illustrates the semiconductor device except for first, second, third, and fourth source/drain contacts 180, 280, 380, and 480. Additionally, FIG. 9 is a plan view illustrating a cut between the first and second source/drain contacts 180 and 280 and uppermost first and second sheet patterns NS1 and NS2. FIG. 10 is a plan view illustrating a cut between first and second lower patterns BP1 and BP2 and lowermost first and second sheet patterns NS1 and NS2. FIG. 11 is a plan view illustrating a cut of the lowermost first and second sheet patterns NS1 and NS2.

Referring to FIGS. 1 through 11, the semiconductor device may include a first lower pattern BP1, a second lower pattern BP2, a third lower pattern BP3, a fourth lower pattern BP4, first channel patterns CH1, second channel patterns CH2, third channel patterns CH3, fourth channel patterns CH4, a first channel separation structure CCW1, a second channel separation structure CCW2, first gate electrodes 120, second gate electrodes 220, third gate electrodes 320, fourth gate electrodes 420, first source/drain patterns 150, second source/drain patterns 250, third source/drain patterns 350, fourth source/drain patterns 450, and a gate separation structure GCS.

A first substrate 100 may include a first surface 100US and a second surface 100BS, which are opposite to each other in a third direction DR3 (e.g., a vertical direction). The gate electrodes (120, 220, 320, and 420), the source/drain patterns (150, 250, 350, and 450), and the channel patterns (CH1, CH2, CH3, and CH4) may be disposed on the first surface 100US of the first substrate 100. Thus, the first surface 100US of the first substrate 100 may correspond to the upper surface of the first substrate 100. The second surface 100BS of the first substrate 100, opposite to the first surface 100US, may correspond to the lower surface of the first substrate 100.

The first substrate 100 may include a semiconductor material. The first substrate 100 may be a silicon (Si) substrate or an Si-on-insulator (SOI) substrate. The first substrate 100 may include, for example, silicon-germanium (SiGe), SiGe-on-insulator (SGOI), indium antimonide, a lead telluride compound, indium arsenide, indium phosphide, gallium arsenide, or gallium antimonide, but is not limited thereto.

The first and second lower patterns BP1 and BP2 may each protrude in the third direction DR3 from the first substrate 100. The first and second lower patterns BP1 and BP2 may protrude from the first surface 100US of the first substrate 100. The first and second lower patterns BP1 and BP2 may each extend in the first direction DR1. The first and second lower patterns BP1 and BP2 may be spaced apart from each other in the second direction DR2.

The third and fourth lower patterns BP3 and BP4 may each protrude in the third direction DR3 from the first substrate 100. The third and fourth lower patterns BP3 and BP4 may protrude from the first surface 100US of the first substrate 100. The third and fourth lower patterns BP3 and BP4 may each extend in the first direction DR1. The third and fourth lower patterns BP3 and BP4 may be spaced apart from each other in the second direction DR2.

For example, the third direction DR3 may be the thickness direction of the first substrate 100. The first and second directions DR1 and DR2 may each be perpendicular to the third direction DR3. The first direction DR1 may be perpendicular to the second direction DR2. For example, the first and second directions DR1 and DR2 may be lateral directions.

The first and third lower patterns BP1 and BP3 may be disposed between the second and fourth lower patterns BP2 and BP4. The first lower pattern BP1 may be disposed between the second and third lower patterns BP2 and BP3.

The first and third lower patterns BP1 and BP3 may be separated by a fin trench FT extending in the first direction DR1. For example, the first surface 100US of the first substrate 100 may correspond to the bottom surface of the fin trench FT.

For example, the first lower pattern BP1 may include a first sidewall BP1_SW1 and a second sidewall BP1_SW2, which are opposite to each other in the second direction DR2. The first and second sidewalls BP1_SW1 and BP1_SW2 of the first lower pattern BP1 may extend in the first direction DR1. The second sidewall BP1_SW2 of the first lower pattern BP1 may be defined by the fin trench FT. The second sidewall BP1_SW2 of the first lower pattern BP1 may define a portion of the fin trench FT. The first sidewall BP1_SW1 of the first lower pattern BP1 may not be defined by the fin trench FT, e.g., may be spaced apart from the fin trench FT.

The second, third, and fourth lower patterns BP2, BP3, and BP4, like the first lower pattern BP1, may each include a first sidewall and a second sidewall, opposite to each other in the second direction DR2. For example, the first sidewall BP1_SW1 of the first lower pattern BP1 may face the first sidewall of the second lower pattern BP2. Since the second sidewall BP1_SW2 of the first lower pattern BP1 and the second sidewall of the third lower pattern BP3 are defined by the fin trench FT (e.g., define a portion of the fin trench FT), the second sidewall BP1_SW2 of the first lower pattern BP1 may face the second sidewall of the third lower pattern BP3.

The first and second lower patterns BP1 and BP2 may be disposed in regions where transistors of the same conductivity type are formed. The third and fourth lower patterns BP3 and BP4 may be disposed in regions where transistors of the same conductivity type are formed. For example, the first lower pattern BP1 may be disposed in a PMOS formation region, and the third lower pattern BP3 may be disposed in an NMOS formation region. As another example, the first and third lower patterns BP1 and BP3 may both be disposed in a PMOS formation region. As yet another example, the first and third lower patterns BP1 and BP3 may both be disposed in an NMOS formation region.

The first, second, third, and fourth lower patterns BP1, BP2, BP3, and BP4 may each be formed by etching a portion of the first substrate 100, or may each include an epitaxial layer grown from the first substrate 100. The first, second, third, and fourth lower patterns BP1, BP2, BP3, and BP4 may each include an elemental semiconductor material, such as Si or Ge. Additionally, the first, second, third, and fourth lower patterns BP1, BP2, BP3, and BP4 may each include a compound semiconductor, for example, a Group IV-IV compound semiconductor or a Group III-V compound semiconductor.

The Group IV-IV compound semiconductor may include a binary or ternary compound containing at least two of carbon (C), Si, germanium (Ge), and tin (Sn), or a compound obtained by doping the binary or ternary compound with a Group IV element.

The Group III-V compound semiconductor may include a binary, ternary, or quaternary compound obtained by combining at least one Group III element, such as aluminum (Al), gallium (Ga), or indium (In), with at least one Group V element, such as phosphorus (P), arsenic (As), or antimony (Sb).

The first and second lower patterns BP1 and BP2 may include the same material. The third and fourth lower patterns BP3 and BP4 may include the same material.

A field insulating film 105 may be disposed on the first surface 100US of the first substrate 100. The field insulating film 105 may fill at least a portion of the fin trench FT that separates the first and third lower patterns BP1 and BP3.

From a cross-sectional perspective, the first and second lower patterns BP1 and BP2 may be disposed between adjacent field insulating films 105 in the second direction DR2. The third lower pattern BP3 and the fourth lower pattern BP4 may be disposed between adjacent portions of the field insulating film 105 in the second direction DR2.

The field insulating film 105 may not be disposed on upper surfaces BP1_US, BP2_US, BP3_US, and BP4_US of the first, second, third, and fourth lower patterns BP1, BP2, BP3, and BP4.

The field insulating film 105 may be disposed on the second sidewall BP1_SW2 of the first lower pattern BP1 and the second sidewall of the third lower pattern BP3. The field insulating film 105 may be in contact with the second sidewall BP1_SW2 of the first lower pattern BP1 and the second sidewall of the third lower pattern BP3. For example, the field insulating film 105 may entirely cover the second sidewall BP1_SW2 of the first lower pattern BP1 and the second sidewall of the third lower pattern BP3, as illustrated. As another example, the field insulating film 105 may cover a portion of the second sidewall BP1_SW2 of the first lower pattern BP1 and/or a portion of the second sidewall of the third lower pattern BP3.

The field insulating film 105 may include an upper surface 105US and a bottom surface 105BS opposite to each other in the third direction DR3. The bottom surface 105BS of the field insulating film 105 may face the first substrate 100. For example, the bottom surface 105BS of the field insulating film 105 may be in contact with the first substrate 100.

The upper surface 105US of the field insulating film 105 is illustrated as having a flat shape, but is not limited thereto. The field insulating film 105 may include, for example, silicon oxide, silicon nitride, silicon oxynitride, or a combination thereof. The field insulating film 105 is illustrated as a single layer, but is not limited thereto.

A plurality of first channel patterns CH1 may be disposed on the first lower pattern BP1. The first channel patterns CH1 may each overlap the first lower pattern BP1 in the third direction DR3. The first channel patterns CH1 may be aligned in the first direction DR1.

A plurality of second channel patterns CH2 may be disposed on the second lower pattern BP2. The second channel patterns CH2 may each overlap the second lower pattern BP2 in the third direction DR3. The second channel patterns CH2 may be aligned in the first direction DR1. The second channel patterns CH2 may be arranged to correspond to the first channel patterns CH1. The second channel patterns CH2 may be spaced apart from the corresponding first channel patterns CH1 in the second direction DR2.

A plurality of third channel patterns CH3 may be disposed on the third lower pattern BP3. The third channel patterns CH3 may each overlap the third lower pattern BP3 in the third direction DR3. The third channel patterns CH3 may be aligned in the first direction DR1.

A plurality of fourth channel patterns CH4 may be disposed on the fourth lower pattern BP4. The fourth channel patterns CH4 may each overlap the fourth lower pattern BP4 in the third direction DR3. The fourth channel patterns CH4 may be aligned in the first direction DR1. The fourth channel patterns CH4 may be arranged to correspond to the third channel patterns CH3. The fourth channel patterns CH4 may be spaced apart from the corresponding third channel patterns CH3 in the second direction DR2.

The first channel patterns CH1, the second channel patterns CH2, the third channel patterns CH3, and the fourth channel patterns CH4 may each include a plurality of sheet patterns spaced apart in the third direction DR3. The first channel patterns CH1, the second channel patterns CH2, the third channel patterns CH3, and the fourth channel patterns CH4 are illustrated as each including three sheet patterns, but are not limited thereto.

The first channel patterns CH1 may include a plurality of first sheet patterns NS1. The first sheet patterns NS1 may be disposed on the upper surface BP1_US of the first lower pattern BP1. The first sheet patterns NS1 may be arranged in the third direction DR3 on the first lower pattern BP1. The first sheet patterns NS1 may be spaced apart in the third direction DR3. The first sheet patterns NS1 may each include an upper surface NS1_US and a bottom surface NS1_BS opposite to each other in the third direction DR3. For example, the upper surfaces NS1_US of uppermost first sheet patterns NS1 may correspond to the upper surfaces of the corresponding first channel patterns CH1.

The third channel patterns CH3 may include a plurality of third sheet patterns NS3. The third sheet patterns NS3 may be disposed on the upper surface BP3_US of the third lower pattern BP3. The third sheet patterns NS3 may be arranged in the third direction DR3 on the third lower pattern BP3. The third sheet patterns NS3 may be spaced apart in the third direction DR3. The third sheet patterns NS3 may each include an upper surface NS3_US and a bottom surface NS3_BS opposite to each other in the third direction DR3.

The second channel patterns CH2 may include a plurality of second sheet patterns NS2. The second sheet patterns NS2 may be disposed on the upper surface BP2_US of the second lower pattern BP2. The fourth channel patterns CH4 may include a plurality of fourth sheet patterns NS4. The fourth sheet patterns NS4 may be disposed on the upper surface BP4_US of the fourth lower pattern BP4.

For example, the first sheet patterns NS1 may each include first sidewalls NS1_SW1 opposite to each other in the first direction DR1 and second sidewalls NS1_SW2 opposite to each other in the second direction DR2. The upper surface NS1_US and the bottom surface NS1_BS of each of the first sheet patterns NS1 may be connected by the first sidewalls NS1_SW1 and the second sidewall NS1_SW2 of the corresponding first sheet pattern NS1. The first sidewalls NS1_SW1 of each of the first sheet patterns NS1 may be connected to and in contact with the first source/drain patterns 150, which will be described later. The description of the first sheet patterns NS1 is also applicable to the second sheet patterns NS2, the third sheet patterns NS3, and the fourth sheet patterns NS4.

The first sheet patterns NS1, the second sheet patterns NS2, the third sheet patterns NS3, and the fourth sheet patterns NS4 may each include one of an elemental semiconductor material, such as Si or Ge, a Group IV-IV compound semiconductor, or a Group III-V compound semiconductor. The first sheet patterns NS1 and the second sheet patterns NS2 may include the same material as, or a different material from, the first lower pattern BP1. The third sheet patterns NS3 and the fourth sheet patterns NS4 may include the same material as, or a different material from, the third lower pattern BP3.

In the semiconductor device, the first, second, third, and fourth lower patterns BP1, BP2, BP3, and BP4 may be silicon lower patterns each including silicon. The first sheet patterns NS1, the second sheet patterns NS2, the third sheet patterns NS3, and the fourth sheet patterns NS4 may be Si sheet patterns each including Si.

As shown in FIG. 4, the first channel separation structure CCW1 may be disposed on the first surface 100US of the first substrate 100. The first channel separation structure CCW1 may be disposed between the first lower pattern BP1 and the second lower pattern BP2. The first channel separation structure CCW1 may extend in the first direction DR1.

The first channel separation structure CCW1 may separate the first and second lower patterns BP1 and BP2. The first channel separation structure CCW1 may separate the first channel patterns CH1 and the second channel patterns CH2. The first and second lower patterns BP1 and BP2 may cover portions of the sidewalls of the first channel separation structure CCW1.

The first channel separation structure CCW1 may be in contact with the first and second lower patterns BP1 and BP2. The first channel separation structure CCW1 may be in contact with the first sidewall BP1_SW1 of the first lower pattern BP1 and the first sidewall of the second lower pattern BP2.

The first channel patterns CH1 and the second channel patterns CH2 may be connected to the first channel separation structure CCW1. The first sheet patterns NS1 and the second sheet patterns NS2 may be connected to the first channel separation structure CCW1. For example, the first channel patterns CH1 and the second channel patterns CH2 may be in contact with the first channel separation structure CCW1. The first sheet patterns NS1 and the second sheet patterns NS2 may protrude from the first channel separation structure CCW1 in the second direction DR2. For example, one of the second sidewalls NS1_SW2 of each of the first sheet patterns NS1 may be connected to the first channel separation structure CCW1, and one of the second sidewalls of each of the second sheet patterns NS2 may be connected to the first channel separation structure CCW1.

The second channel separation structure CCW2 may be disposed on the first surface 100US of the first substrate 100. The second channel separation structure CCW2 may be disposed between the third and fourth lower patterns BP3 and BP4. The second channel separation structure CCW2 may extend in the first direction DR1. The second channel separation structure CCW2 may be spaced apart from the first channel separation structure CCW1 in the second direction DR2.

The second channel separation structure CCW2 may separate the third and fourth lower patterns BP3 and BP4. The second channel separation structure CCW2 may separate the third channel patterns CH3 and the fourth channel patterns CH4. The third and fourth lower patterns BP3 and BP4 may cover portions of the sidewalls of the second channel separation structure CCW2.

The second channel separation structure CCW2 may be in contact with the third and fourth lower patterns BP3 and BP4. The second channel separation structure CCW2 may be in contact with the first sidewall of the third lower pattern BP3 and the first sidewall of the fourth lower pattern BP4.

The third channel patterns CH3 and the fourth channel patterns CH4 may be connected to the second channel separation structure CCW2. The third sheet patterns NS3 and the fourth sheet patterns NS4 may be connected to the second channel separation structure CCW2. For example, the third channel patterns CH3 and the fourth channel patterns CH4 may be in contact with the second channel separation structure CCW2. The third sheet patterns NS3 and the fourth sheet patterns NS4 may protrude from the second channel separation structure CCW2 in the second direction DR2. For example, one of the second sidewalls of each of the third sheet patterns NS3 may be connected to the second channel separation structure CCW2, and one of the second sidewalls of each of the fourth sheet patterns NS4 may be connected to the second channel separation structure CCW2.

As shown in FIGS. 4-5, the first and second channel separation structures CCW1 and CCW2 may each include a first core separation pattern 161, a second core separation pattern 162, and a liner separation pattern 163. The liner separation patterns 163 may include, for example, silicon oxide. The first core separation patterns 161 and the second core separation patterns 162 may each include a material having an etch selectivity with respect to silicon oxide. The first core separation patterns 161 and the second core separation patterns 162 may each include, for example, silicon nitride, silicon oxynitride, silicon oxycarbonitride, silicon boron nitride, silicon oxyboronitride, silicon oxycarbide, or a combination thereof.

The first core separation patterns 161 and the second core separation patterns 162 are illustrated as single layers but are not limited thereto. The first and second channel separation structures CCW1 and CCW2 may be formed simultaneously, and may thus include the same material.

The description of the second channel separation structure CCW2 may be substantially the same as or similar to that of the first channel separation structure CCW1. Therefore, the description of the first channel separation structure CCW1 is also applicable to the second channel separation structure CCW2. The first channel separation structure CCW1 will be described later in further detail.

As shown in FIG. 4, in the semiconductor device, a depth H11 from the upper surface BP1_US of the first lower pattern BP1 to the lowermost portion of the first channel separation structure CCW1 may be equal to or greater than a depth H12 from the upper surface BP1_US of the first lower pattern BP1 to the bottom surface 105BS of the field insulating film 105.

The gate separation structure GCS may be disposed on the first surface 100US of the first substrate 100. The gate separation structure GCS may extend in the first direction DR1. The gate separation structure GCS may be disposed on the field insulating film 105. A portion of the gate separation structure GCS may be disposed within an upper interlayer insulating film 190.

The gate separation structure GCS may be in contact with the field insulating film 105. The gate separation structure GCS may protrude in the third direction DR3 beyond the upper surface 105US of the field insulating film 105. For example, a portion of the gate separation structure GCS may be recessed into the field insulating film 105.

The gate separation structure GCS may be disposed between the first and second channel separation structures CCW1 and CCW2. The first channel patterns CH1, the second channel patterns CH2, the third channel patterns CH3, and the fourth channel patterns CH4 may be disposed between the first and second channel separation structures CCW1 and CCW2 and the gate separation structure GCS.

For example, the depth H11 from the upper surface BP1_US of the first lower pattern BP1 to the lowermost portion of the first channel separation structure CCW1 may be greater than a depth H13 from the upper surface BP1_US of the first lower pattern BP1 to the lowermost portion of the gate separation structure GCS.

The gate separation structure GCS may include an insulating material. For example, the gate separation structure GCS may include silicon nitride, silicon oxynitride, silicon oxide, silicon oxycarbonitride, silicon boron nitride, silicon oxyboronitride, silicon oxycarbide, or a combination thereof. The gate separation structure GCS is illustrated as a single layer, but is not limited thereto.

The first gate structures GS1, the second gate structures GS2, the third gate structures GS3, and the fourth gate structures GS4 may be disposed on the first surface 100US of the first substrate 100. The first gate structures GS1, the second gate structures GS2, the third gate structures GS3, and the fourth gate structures GS4 may be in contact with the upper surface 105US of the field insulating film 105.

A plurality of first gate structures GS1 may be disposed between the first channel separation structure CCW1 and the gate separation structure GCS. The first gate structures GS1 may be in contact with the first channel separation structure CCW1 and the gate separation structure GCS. The first gate structures GS1 may be adjacent to each other in the first direction DR1.

The first gate structures GS1 may be disposed on the first lower pattern BP1. For example, the first gate structures GS1 may be in contact with the upper surface BP1_US of the first lower pattern BP1. The first channel patterns CH1 may be disposed between the first gate structures GS1 and the first channel separation structure CCW1. The first sheet patterns NS1 may be disposed between the first gate structures GS1 and the first channel separation structure CCW1. Since the first sheet patterns NS1 are each connected to the first channel separation structure CCW1, the first gate structures GS1 may not surround each of the first sheet patterns NS1 from a cross-sectional perspective.

The first gate structures GS1 may include first gate electrodes 120 and first gate insulating films 130. The first gate electrodes 120 may be disposed on the first lower pattern BP1. The first gate insulating films 130 may be disposed between the first gate electrodes 120 and the first channel patterns CH1. For example, the first gate insulating films 130 may be disposed between the first gate electrode 120 and the first sheet pattern NS1.

The first gate insulating films 130 may extend along the upper surface 105US of the field insulating film 105 and the upper surface BP1_US of the first lower pattern BP1. The first gate insulating films 130 may be in contact with the upper surface 105US of the field insulating film 105 and the upper surface BP1_US of the first lower pattern BP1. From a cross-sectional perspective such as that illustrated in FIG. 4, the first gate insulating films 130 may extend along the sidewalls of the first channel separation structure CCW1. The first gate insulating films 130 may be in contact with the first channel separation structure CCW1. The first gate electrodes 120 may not be in contact with the sidewalls of the first channel separation structure CCW1. The first gate insulating films 130 may not extend along the sidewall of the gate separation structure GCS. The first gate electrodes 120 may be in contact with the sidewall of the gate separation structure GCS. The first gate insulating films 130 may be disposed along portions of the perimeters of the first sheet patterns NS1.

The first gate structures GS1 may include first inner gate structures INT_GS1. The first inner gate structures INT_GS1 may be disposed between the first lower pattern BP1 and the first sheet patterns NS1, and between adjacent first sheet patterns NS1 in the third direction DR3. The first inner gate structures INT_GS1 may be in contact with the upper surface BP1_US of the first lower pattern BP1, the upper surfaces NS1_US of the first sheet patterns NS1, and the bottom surfaces NS1_BS of the first sheet patterns NS1. In the semiconductor device, the first gate insulating films 130 included in the first inner gate structures INT_GS1 may be in contact with the first source/drain patterns 150, which will be described later.

The description of the second, third, and fourth gate structures GS2, GS3, and GS4 may be substantially the same as or similar to the description of the first gate structures GS1. Therefore, the description of the first gate structures GS1 is also applicable to the second to fourth gate structures GS2, GS3, and GS4.

A plurality of second gate structures GS2 may be disposed between the first channel separation structure CCW1 and the gate separation structure GCS. The first channel separation structure CCW1 may be disposed between the first gate structures GS1 and the second gate structures GS2. The second gate structures GS2 may be adjacent to each other in the first direction DR1. The second gate structures GS2 may be spaced apart from the first gate structures GS1 in the second direction DR2.

The second gate structures GS2 may be disposed on the second lower pattern BP2. The second channel patterns CH2 may be disposed between the second gate structures GS2 and the first channel separation structure CCW1. The second gate structures GS2 may include second gate electrodes 220 and second gate insulating films 230. The second gate structures GS2 may include second inner gate structures disposed between the second lower pattern BP2 and the second sheet patterns NS2, and between adjacent second sheet patterns NS2 in the third direction DR3.

A plurality of third gate structures GS3 may be disposed between the second channel separation structure CCW2 and the gate separation structure GCS. The third gate structures GS3 may be in contact with the second channel separation structure CCW2 and the gate separation structure GCS. The third gate structures GS3 may be adjacent to each other in the first direction DR1. The third gate structures GS3 may be spaced apart from the first gate structures GS1 in the second direction DR2.

The third gate structures GS3 may be disposed on the third lower pattern BP3. The third channel patterns CH3 may be disposed between the third gate structures GS3 and the second channel separation structure CCW2. The third gate structures GS3 may include third gate electrodes 320 and third gate insulating films 330. The third gate structures GS3 may include third inner gate structures INT_GS3 disposed between the third lower pattern BP3 and the third sheet patterns NS3, and between adjacent third sheet patterns NS3 in the third direction DR3. In the semiconductor device, the third gate insulating films 330 included in the third inner gate structure INT_GS3 may be in contact with the third source/drain patterns 350, which will be described later.

A plurality of fourth gate structures GS4 may be disposed between the second channel separation structure CCW2 and the gate separation structure GCS. The second channel separation structure CCW2 may be disposed between the third gate structures GS3 and the fourth gate structures GS4. The fourth gate structures GS4 may be adjacent to each other in the first direction DR1. The fourth gate structures GS4 may be spaced apart from the third gate structures GS3 in the second direction DR2.

The fourth gate structures GS4 may be disposed on the fourth lower pattern BP4. The fourth channel patterns CH4 may be disposed between the fourth gate structures GS4 and the second channel separation structure CCW2. The fourth gate structures GS4 may include fourth gate electrodes 420 and fourth gate insulating films 430. The fourth gate structures GS4 may include fourth inner gate structures disposed between the fourth lower pattern BP4 and the fourth sheet patterns NS4, and between adjacent fourth sheet patterns NS4 in the third direction DR3.

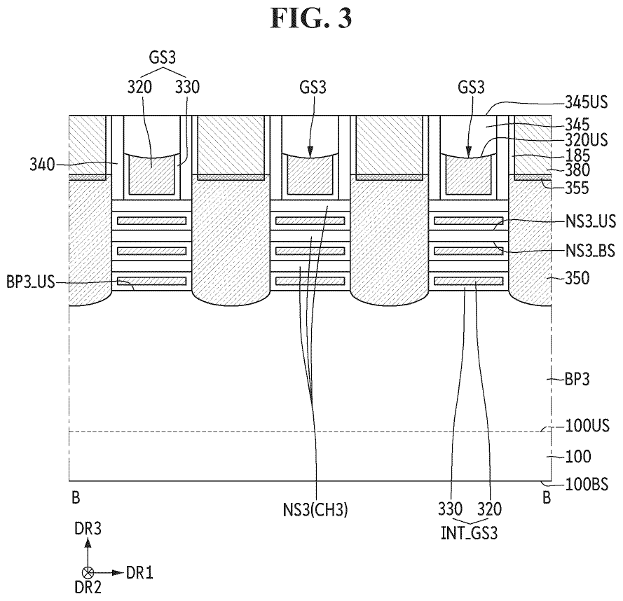

From a cross-sectional perspective such as those illustrated in FIGS. 2 and 3, upper surfaces 120US of the first gate electrodes 120 and upper surfaces 320US of the third gate electrodes 320 are illustrated as having concave curved surfaces, but are not limited thereto. The upper surfaces 120US of the first gate electrodes and the upper surfaces 320US of the third gate electrodes 320 may, for example, be flat.

From a cross-sectional perspective such as that illustrated in FIG. 4, the upper surfaces of the first gate electrodes 120 and the upper surfaces of the second gate electrodes 220 may be flat. The upper surfaces of the third gate electrodes 320 and the upper surfaces of the fourth gate electrodes 420 may also be flat.

The first gate electrodes 120, the second gate electrodes 220, the third gate electrodes 320, and the fourth gate electrodes 420 may each include one of a metal, a metal alloy, a conductive metal nitride, a metal silicide, a doped semiconductor material, a conductive metal oxide, a conductive metal oxynitride, or a combination thereof. The first gate electrodes 120, the second gate electrodes 220, the third gate electrodes 320, and the fourth gate electrodes 420 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel-platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. Herein, a conductive metal oxide and conductive metal oxynitride may include oxidized forms of the aforementioned materials but are not limited thereto.

The first gate insulating films 130, the second gate insulating films 230, the third gate insulating films 330, and the fourth gate insulating films 430 may include silicon oxide, silicon oxynitride, silicon nitride, or a high-k material with a dielectric constant greater than that of silicon oxide. The high-k material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The first gate insulating films 130, the second gate insulating films 230, the third gate insulating films 330, and the fourth gate insulating films 430 are illustrated as single layers, but are not limited thereto. For example, the first gate insulating films 130, the second gate insulating films 230, the third gate insulating films 330, and the fourth gate insulating films 430 may include a plurality of films. For example, the first gate insulating films 130 may include interfacial layers disposed between the first channel patterns CH1 and the first gate electrodes 120, and high-k insulating films. For example, the interfacial layers may not be formed along the profile of the upper surface 105US of the field insulating film 105.

According to some implementations of the present disclosure, the semiconductor device may include a negative capacitance (NC) FET utilizing a negative capacitor. For example, the first gate insulating films 130, the second gate insulating films 230, the third gate insulating films 330, and the fourth gate insulating films 430 may each include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one of hafnium oxide, hafnium zirconium oxide, barium strontium titanium oxide, barium titanium oxide, or lead zirconium titanium oxide. The hafnium zirconium oxide may be, for example, a material obtained by doping hafnium oxide with zirconium (Zr). The hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), or Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one of Gd, Si, Zr, Al, or Y.

If the dopant is Al, the ferroelectric material film may contain 3 to 8 atomic % (at %) of Al. Here, the proportion of the dopant may be the ratio of Al to the sum of Hf and Al.

If the dopant is Si, the ferroelectric material film may contain 2 to 10 at % of Si. If the dopant is Y, the ferroelectric material film may contain 2 to 10 at % of Y. If the dopant is Gd, the ferroelectric material film may contain 1 to 7 at % of Gd. If the dopant is Zr, the ferroelectric material film may contain 50 to 80 at % of Zr.

The paraelectric material film may have paraelectric properties. For example, the paraelectric material film may include at least one of silicon oxide or a high-k metal oxide. The high-k metal oxide may include at least one of hafnium oxide, zirconium oxide, or aluminum oxide, but the material is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the thickness is not limited thereto. Since the critical thickness for exhibiting ferroelectric properties may vary from one ferroelectric material to another, the thickness of the ferroelectric material film may vary depending on its material.

For example, the first gate insulating films 130, the second gate insulating films 230, the third gate insulating films 330, and the fourth gate insulating films 430 may each include one ferroelectric material film. As another example, the first gate insulating films 130, the second gate insulating films 230, the third gate insulating films 330, and the fourth gate insulating films 430 may each include a plurality of ferroelectric material films that are spaced apart from one another. The first gate insulating films 130, the second gate insulating films 230, the third gate insulating films 330, and the fourth gate insulating films 430 may each have a layered film structure in which a plurality of ferroelectric material films and a plurality of paraelectric material films are alternately stacked.

First gate spacers 140 may be disposed on the sidewalls of the first gate structures GS1. Third gate spacers 340 may be disposed on the sidewalls of the third gate structures GS3. Second gate spacers and fourth gate spacers may be disposed on the sidewalls of the second gate structures GS2 and the sidewalls of the fourth gate structures GS4, respectively.

For example, the first gate spacers 140 may not be disposed between the first lower pattern BP1 and the first sheet patterns NS1, or between the adjacent first sheet patterns NS1 in the third direction DR3. The third gate spacers 340 may not be disposed between the third lower pattern BP3 and the third sheet patterns NS3, or between adjacent third sheet patterns NS3 in the third direction DR3.

The first gate spacers 140 and the third gate spacers 340 may include, for example, silicon nitride, silicon oxynitride, silicon oxide, silicon oxycarbonitride, silicon boron nitride, silicon oxyboronitride, silicon oxycarbide, or a combination thereof. The first gate spacers 140 and the third gate spacers 340 are illustrated as single layers but are not limited thereto.

First gate capping patterns 145 may be disposed on the first gate structures GS1 and the second gate structures GS2. The first gate capping patterns 145 may be disposed on the upper surfaces 120US of the first gate electrodes 120 and the upper surfaces 220 of the second gate electrodes 220. Upper surfaces 145US of the first gate capping patterns 145 may be on the same plane as an upper surface GCS_US of the gate separation structure GCS.

Second gate capping patterns 345 may be disposed on the third gate structures GS3 and the fourth gate structures GS4. The second gate capping patterns 345 may be disposed on the upper surfaces 320US of the third gate structures 320 and the upper surfaces of the fourth gate electrodes 420. Upper surfaces 345US of the second gate capping patterns 345 may be on the same plane as the upper surface GCS_US of the gate separation structure GCS.

The first gate capping patterns 145 may be disposed on the first channel separation structure CCW1. The first gate capping patterns 145 may be disposed on an upper surface CCW1_US of the first channel separation structure CCW1. The second gate capping patterns 345 may be disposed on the second channel separation structure CCW2. The second gate capping patterns 345 may be disposed on an upper surface CCW2_US of the second channel separation structure CCW2. From a cross-sectional perspective such as that illustrated in FIG. 4, the upper surfaces CCW1_US and CCW2_US of the first and second channel separation structures CCW1 and CCW2 may be lower than the upper surface GCS_US of the gate separation structure GCS based on the bottom surface 105BS of the field insulating film 105.

The first gate insulating films 130 and the second gate insulating films 230 may not be disposed between the first gate capping patterns 145 and the first channel separation structure CCW1. For example, the first gate insulating films 130 and the second gate insulating films 230 may not extend along the boundaries between the first gate capping patterns 145 and the first channel separation structure CCW1. The first gate insulating films 130 and the second gate insulating films 230 may not be disposed between the first gate capping patterns 145 and the first channel separation structure CCW1.

The first gate capping patterns 145 and the second gate capping patterns 345 may include, for example, one of silicon nitride, silicon oxynitride, silicon carbonitride, silicon oxycarbonitride, or a combination thereof.

The first source/drain patterns 150 may be disposed on the first lower pattern BP1. The first source/drain patterns 150 may be disposed adjacent to the first gate structures GS1 in the first direction DR1. The first source/drain patterns 150 may be disposed between the first channel separation structure CCW1 and the gate separation structure GCS. The first source/drain patterns 150 may be connected to the first channel patterns CH1. The first source/drain patterns 150 may be in contact with the first channel patterns CH1. The first source/drain patterns 150 may be in contact with each of the first sheet patterns NS1. For example, the first source/drain patterns 150 may be in contact with the first inner gate structures INT_GS1.

The second source/drain patterns 250 may be disposed on the second lower pattern BP2. The second source/drain patterns 250 may be disposed adjacent to the second gate structures GS2 in the first direction DR1. The second source/drain patterns 250 may be disposed between the first channel separation structure CCW1 and the gate separation structure GCS. Although not illustrated, the second source/drain patterns 250 may be connected to the second channel patterns CH2. The second source/drain patterns 250 may be in contact with the second channel patterns CH2.

The third source/drain patterns 350 may be disposed on the third lower pattern BP3. The third source/drain patterns 350 may be disposed adjacent to the third gate structures GS3 in the first direction DR1. The third source/drain patterns 350 may be disposed between the second channel separation structure CCW2 and the gate separation structure GCS. The third source/drain patterns 350 may be connected to the third channel patterns CH3. The third source/drain patterns 350 may be in contact with the third channel patterns CH3. The third source/drain patterns 350 may be in contact with each of the third sheet patterns NS3. For example, the third source/drain patterns 350 may be in contact with the third inner gate structures INT_GS3.

The fourth source/drain patterns 450 may be disposed on the fourth lower pattern BP4. The fourth source/drain patterns 450 may be disposed adjacent to the fourth gate structures GS4 in the first direction DR1. The fourth source/drain patterns 450 may be disposed between the second channel separation structure CCW2 and the gate separation structure GCS. Although not illustrated, the fourth source/drain patterns 450 may be connected to the fourth channel patterns CH4. The fourth source/drain patterns 450 may be in contact with the fourth channel patterns CH4.

The first channel separation structure CCW1 may be disposed between the first source/drain patterns 150 and the second source/drain patterns 250. The first source/drain patterns 150 and the second source/drain patterns 250 may be spaced apart from each other in the second direction DR2. The first source/drain patterns 150 and the second source/drain patterns 250 may be in contact with the first channel separation structure CCW1.

For example, portions of the first source/drain patterns 150 may overlap the first channel separation structure CCW1 along the third direction DR3. The first source/drain patterns 150 may include overlapping portions 150_OVR that overlap the first channel separation structure CCW1 along the third direction DR3. Portions of the first source/drain patterns 150 may extend across the first channel separation structure CCW1. Similarly, portions of the second source/drain patterns 250 may overlap the first channel separation structure CCW1 along the third direction DR3. Portions of the second source/drain patterns 250 may extend across the first channel separation structure CCW1.

The second channel separation structure CCW2 may be disposed between the third source/drain patterns 350 and the fourth source/drain patterns 450. The third source/drain patterns 350 and the fourth source/drain patterns 450 may be spaced apart from each other in the second direction DR2. The third source/drain patterns 350 and the fourth source/drain patterns 450 may be in contact with the second channel separation structure CCW2.

For example, portions of the third source/drain patterns 350 and portions of the fourth source/drain patterns 450 may overlap the second channel separation structure CCW2 along the third direction DR3. Portions of the third source/drain patterns 350 and portions of the fourth source/drain patterns 450 may extend across the second channel separation structure CCW2.

The first source/drain patterns 150, the second source/drain patterns 250, the third source/drain patterns 350, and the fourth source/drain patterns 450 may be disposed on the first surface 100US of the first substrate 100. The first source/drain patterns 150 may be included in the sources/drains of transistors that use the first sheet patterns NS1 as channel regions. The second source/drain patterns 250 may be included in the sources/drains of transistors that use the second sheet patterns NS2 as channel regions. The third source/drain patterns 350 may be included in the sources/drains of transistors that use the third sheet patterns NS3 as channel regions. The fourth source/drain patterns 450 may be included in the sources/drains of transistors that use the fourth sheet patterns NS4 as channel regions.

The first source/drain patterns 150, the second source/drain patterns 250, the third source/drain patterns 350, and the fourth source/drain patterns 450 may each include epitaxial patterns. The first source/drain patterns 150, the second source/drain patterns 250, the third source/drain patterns 350, and the fourth source/drain patterns 450 may each include a semiconductor material.

The first source/drain patterns 150 and the second source/drain patterns 250 may include dopants of the same conductivity type. The first source/drain patterns 150 and the second source/drain patterns 250 may include either p-type dopants or n-type dopants. The third source/drain patterns 350 and the fourth source/drain patterns 450 may include dopants of the same conductivity type. The third source/drain patterns 350 and the fourth source/drain patterns 450 may include either a p-type dopant or an n-type dopant. The p-type dopant may include at least one of boron (B) or Ga, but is not limited thereto. The n-type dopant may include at least one of P, As, Sb, or bismuth (Bi), but is not limited thereto.

The following description focuses on the first channel separation structure CCW1. The description of the first channel separation structure CCW1 is also applicable to the second channel separation structure CCW2.

The first core separation pattern 161 of the first channel separation structure CCW1 may protrude in the third direction DR3 from or above the first surface 100US of the first substrate 100. The first core separation pattern 161 may be disposed between the first lower pattern BP1 and the second lower pattern BP2, and between the first channel patterns CH1 and the second channel patterns CH2. The first core separation pattern 161 may overlap the first and second lower patterns BP1 and BP2 along the second direction DR2. The first core separation pattern 161 may overlap the first channel patterns CH1 and the second channel patterns CH2 along the second direction DR2. The first core separation pattern 161 may include sidewalls 161_SW extending in the first direction DR1.

As shown in FIG. 7, the first core separation pattern 161 may include a lower core separation pattern 161BP and an upper core separation pattern 161UP. The upper core separation pattern 161UP may be disposed on the lower core separation pattern 161BP. The lower core separation pattern 161BP may be disposed between the upper core separation pattern 161UP and the first substrate 100. For example, the lower core separation pattern 161BP and the upper core separation pattern 161UP may each include silicon nitride, silicon oxynitride, silicon oxycarbonitride, silicon boron nitride, silicon oxyboronitride, silicon oxycarbide, or a combination thereof. In some implementations, the lower core separation pattern 161BP and the upper core separation pattern 161UP may include the same insulating material. In this case, the boundary between the lower core separation pattern 161BP and the upper core separation pattern 161UP may not be distinguishable. As another example, the lower core separation pattern 161BP and the upper core separation pattern 161UP may include different insulating materials.

The second core separation pattern 162 may be disposed on the first core separation pattern 161. The first core separation pattern 161 may be disposed between the second core separation pattern 162 and the first substrate 100. The boundary between the first core separation pattern 161 and the second core separation pattern 162 may not be distinguishable, e.g., based on the first and second core separation patterns 161, 162 including the same material.

The liner separation pattern 163 may extend along the sidewalls 161_SW and the bottom surface of the first core separation pattern 161. The liner separation pattern 163 may be disposed between the sidewalls 161_SW of the first core separation pattern 161 and the first sidewalls BP1_SW1 of the first lower pattern BP1, and between the sidewalls 161_SW of the first core separation pattern 161 and the first sidewalls of the second lower pattern BP2. The liner separation pattern 163 may be in contact with the sidewalls 161_SW of the first core separation pattern 161 and the first sidewalls of the second lower pattern BP2. The liner separation pattern 163 may not be disposed on the sidewalls of the second core separation pattern 162.

For example, the liner separation pattern 163 may be disposed on portions of the sidewalls 161_SW of the first core separation pattern 161 defined by the lower core separation pattern 161BP. The liner separation pattern 163 may not be disposed on portions of the sidewalls 161_SW of the first core separation pattern 161 defined by the upper core separation pattern 161UP.

From a cross-sectional perspective such as that illustrated in FIG. 4, the liner separation pattern 163 may not be disposed between the first lower pattern BP1 and the first sheet patterns NS1, or between the adjacent first sheet patterns NS1 in the third direction DR3. Similarly, the liner separation pattern 163 may not be disposed between the second lower pattern BP2 and the second sheet patterns NS2, or between the adjacent second sheet patterns NS2 in the third direction DR3. The first gate structures GS1 and the second gate structures GS2 may be in contact with the sidewalls 161_SW of the first core separation pattern 161. The first gate insulating films 130 and the second gate insulating films 230 may be in contact with the sidewalls 161_SW of the first core separation pattern 161.

The liner separation pattern 163 may be in contact between the first core separation pattern 161 and the first sheet patterns NS1. Similarly, the liner separation pattern 163 may be in contact with the first core separation pattern 161 and the second sheet patterns NS2, between the first core separation pattern 161 and the second sheet patterns NS2. The liner separation pattern 163 may connect each of the first sheet patterns NS1 to the first core separation pattern 161. The liner separation pattern 163 may connect each of the second sheet patterns NS2 to the first core separation pattern 161.

From a cross-sectional perspective such as those illustrated in FIGS. 4 and 7, a thickness t3 of the liner separation pattern 163 in the third direction DR3 between the first core separation pattern 161 and the first sheet patterns NS1, and between the first core separation pattern 161 and the second sheet patterns NS2, may remain uniform along a direction away from the first sheet patterns NS1 and the second sheet patterns NS2.

As shown in FIGS. 7-8, the liner separation pattern 163 may include a lower liner separation pattern 163BP and a plurality of connecting liner separation patterns 163CP. Each of the connecting liner separation patterns 163CP is spaced apart from the lower liner separation pattern 163BP in the third direction DR3. Each of the connecting liner separation patterns 163CP is not directly connected to the lower liner separation pattern 163BP.

The lower liner separation pattern 163BP may be disposed between the first lower pattern BP1 and the first core separation pattern 161, and between the second lower pattern BP2 and the first core separation pattern 161. The lower liner separation pattern 163BP may be in contact with the first and second lower patterns BP1 and BP2.

The connecting liner separation patterns 163CP may be disposed between the first sheet patterns NS1 and the first core separation pattern 161, and between the second sheet patterns NS2 and the first core separation pattern 161. The connecting liner separation patterns 163CP may connect each of the first sheet patterns NS1 and each of the second sheet patterns NS2 to the first core separation pattern 161.

Referring to FIGS. 5 and 8, the second core separation pattern 162 may be in contact with the first source/drain patterns 150 and the second source/drain patterns 250. In some implementations, the liner separation pattern 163 is not disposed between the first source/drain patterns 150 and the first core separation pattern 161, or between the second source/drain patterns 250 and the first core separation pattern 161. The first source/drain patterns 150 and the second source/drain patterns 250 may be in contact with the sidewalls 161_SW of the first core separation pattern 161.

Referring to FIGS. 1, 4, 5, and 7 to 11, the first channel separation structure CCW1 may include a first region CCW1_R1 and a second region CCW1_R2. The first region CCW1_R1 of the first channel separation structure CCW1 may be a region that is in contact with the first gate structures GS1 and the second gate structures GS2. The first region CCW1_R1 of the first channel separation structure CCW1 may overlap the first gate structures GS1 and the second gate structures GS2 in the second direction DR2. The second region CCW1_R2 of the first channel separation structure CCW1 may be a region that is in contact with the first source/drain patterns 150 and the second source/drain patterns 250. The second region CCW1_R2 of the first channel separation structure CCW1 may overlap the first source/drain patterns 150 and the second source/drain patterns 250 in the second direction DR2. The first region CCW1_R1 and the second region CCW1_R2 may be adjacent to one another along the first direction DR1.

FIG. 7 is a diagram for explaining the shape of the first region CCW1_R1 of the first channel separation structure CCW1, and FIG. 8 is a diagram for explaining the shape of the second region CCW1_R2 of the first channel separation structure CCW1.

Referring to FIGS. 4 and 7, the first region CCW1_R1 of the first channel separation structure CCW1 may include the first core separation pattern 161 and the liner separation pattern 163 of the first channel separation structure CCW1. The first region CCW1_R1 of the first channel separation structure CCW1 may not include the second core separation pattern 162 of the first channel separation structure CCW1. In the first region CCW1_R1 of the first channel separation structure CCW1, the first core separation pattern 161 may include the lower core separation pattern 161BP and the upper core separation pattern 161UP, and the liner separation pattern 163 may include the lower liner separation pattern 163BP and the connecting liner separation patterns 163CP.

In the first region CCW1_R1 of the first channel separation structure CCW1, the first core separation pattern 161 may have a “T” shaped cross-section. The first core separation pattern 161 may include a first portion 161P1, a second portion 161P2, and a connecting portion 161CP. The connecting portion 161CP of the first core separation pattern 161 may be disposed between the first and second portions 161P1 and 161P2 of the first core separation pattern 161.

The first portion 161P1 of the first core separation pattern 161 may overlap the first and second lower patterns BP1 and BP2 along the second direction DR2. The liner separation pattern 163 may be disposed between the first portion 161P1 of the first core separation pattern 161 and the first lower pattern BP1, and between the first portion 161P1 of the first core separation pattern 161 and the second lower pattern BP2. For example, the lower liner separation pattern 163BP may be disposed between the first portion 161P1 of the first core separation pattern 161 and the first lower pattern BP1, and between the first portion 161P1 of the first core separation pattern 161 and the second lower pattern BP2.

The first portion 161P1 of the first core separation pattern 161 may overlap each of the first sheet patterns NS1 and each of the second sheet patterns NS2 along the second direction DR2. Each of the first sheet patterns NS1 and each of the second sheet patterns NS2 may be connected to the first portion 161P1 of the first core separation pattern 161 through the liner separation pattern 163. For example, each of the first sheet patterns NS1 and each of the second sheet patterns NS2 may be connected to the first portion 161P1 of the first core separation pattern 161 through the connecting liner separation patterns 163CP.

Based on the bottom surface 105BS of the field insulating film 105, the connecting portion 161CP and the second portion 161P2 of the first core separation pattern 161 may be disposed above the upper surfaces of the first channel patterns CH1 and the upper surfaces of the second channel patterns CH2. The second portion 161P2 of the first core separation pattern 161 may be in contact with the first gate capping patterns 145. The liner separation pattern 163 may not be disposed on the sidewalls of the connecting portion 161CP of the first core separation pattern 161 and the sidewalls of the second portion 161P2 of the first core separation pattern 161.

At the boundary between the connecting portion 161CP and the second portion 161P2 of the first core separation pattern 161, the slope of the sidewalls 161_SW of the first core separation pattern 161 may change sharply. At the boundary between the connecting portion 161CP and the first portion 161P1 of the first core separation pattern 161, the slope of the sidewalls 161_SW of the first core separation pattern 161 may change sharply. For example, a slope SS3 of the sidewalls 161_SW of the first core separation pattern 161 at the connecting portion 161CP may be smaller than a slope SS1 of the sidewalls 161_SW at the first portion 161P1. The slope SS3 of the sidewalls 161_SW at the connecting portion 161CP may also be smaller than a slope SS2 of the sidewalls 161_SW at the second portion 161P2. The slopes SS1, SS2, and SS3 of the sidewalls 161_SW of the first core separation pattern 161 may be determined by the angles formed between a line extending in the second direction DR2 and the sidewalls 161_SW of the first core separation pattern 161 in a cross-sectional view. The comparison of the slopes SS1, SS2, and SS3 may be based on the absolute values of the slopes determined from the aforementioned angles.

The upper core separation pattern 161UP may include the connecting portion 161CP and the second portion 161P2 of the first core separation pattern 161. The lower core separation pattern 161BP may include the first portion 161P1 of the first core separation pattern 161.

At the connecting portion 161CP of the first core separation pattern 161, the width of the first core separation pattern 161 in the second direction DR2 may increase as the distance from the bottom surface 105BS of the field insulating film 105 increases. The width of the first core separation pattern 161 in the second direction DR2 at the first portion 161P1 and the second portion 161P2 may also increase as the distance from the bottom surface 105BS of the field insulating film 105 increases.

Referring to FIGS. 5 and 8, the second region CCW1_R2 of the first channel separation structure CCW1 may include the first core separation pattern 161, the second core separation pattern 162, and the liner separation pattern 163. In the second region CCW1_R2 of the first channel separation structure CCW1, the first core separation pattern 161 may not include the upper core separation pattern 161UP in FIG. 7. The liner separation pattern 163 in the second region CCW1_R2 may not include the connecting liner separation patterns 163CP in FIG. 7.

The width of the second core separation pattern 162 in the second direction DR2 may continuously increase as the distance from the bottom surface 105BS of the field insulating film 105 increases. In the second region CCW1_R2 of the first channel separation structure CCW1, the width of the first core separation pattern 161 in the second direction DR2 may continuously increase as the distance from the bottom surface 105BS of the field insulating film 105 increases.

There may be a step difference between the first and second core separation patterns 161 and 162. For example, as shown in FIG. 9, a width W21 of the uppermost portion of the first core separation pattern 161 may be greater than a width W22 of the lowermost portion of the second core separation pattern 162.

The first core separation pattern 161 may include a first width centerline WCL1 extending in the third direction DR3. The second core separation pattern 162 may include a second width centerline WCL2 extending in the third direction DR3. For example, the first width centerline WCL1 may be aligned with the second width centerline WCL2 in the third direction DR3. For example, the extension line of the first width centerline WCL1 may coincide with the second width centerline WCL2.

The first width centerline WCL1 may be an imaginary line dividing the width W21 of the uppermost portion of the first core separation pattern 161 in half. The second width centerline WCL2 may be an imaginary line dividing the width W22 of the lowermost portion of the second core separation pattern 162 in half.

In some implementations (e.g., a modification of the configuration of FIG. 8), the first width centerline WCL1 may be spaced apart from the second width centerline WCL2 in the second direction DR2. The first width centerline WCL1 may be misaligned with the second width centerline WCL2 in the third direction DR3.

In the second region CCW1_R2 of the first channel separation structure CCW1, a height H15 from the bottom surface 105BS of the field insulating film to the uppermost portion of the first core separation pattern 161 may be less than a height H16 from the bottom surface 105BS of the field insulating film 105 to the uppermost portions of the first source/drain patterns 150. Here, the uppermost portions of the first source/drain patterns 150 may be included in a source/drain structure comprising the first source/drain patterns 150 and first contact silicide films 155. The uppermost portions of the first source/drain patterns 150 may be the portions farthest from the bottom surface 105BS of the field insulating film 105.

Portions of the first source/drain patterns 150 may overlap the first core separation pattern 161 in the third direction DR3. The overlapping portions 150_OVR of the first source/drain patterns 150 may overlap the first core separation pattern 161 in the third direction DR3. The overlapping portions 150_OVR of the first source/drain patterns 150 may extend across the first core separation pattern 161.

Portions of the second source/drain patterns 250 may overlap the first core separation pattern 161 in the third direction DR3. Portions of the second source/drain patterns 250 may extend across the first core separation pattern 161.

Referring to FIGS. 4 and 5, a height H15 from the bottom surface 105BS of the field insulating film 105 to the uppermost portion of the first core separation pattern 161 in the second region CCW1_R2 of the first channel separation structure CCW1 may be less than a height H14 from the bottom surface 105BS of the field insulating film 105 to the upper surfaces of the first channel patterns CH1.

In the first region CCW1_R1 of the first channel separation structure CCW1, the upper surface CCW1_US of the first channel separation structure CCW1 may be the upper surface 161_US of the first core separation pattern 161. In the second region CCW1_R2 of the first channel separation structure CCW1, the upper surface CCW1_US of the first channel separation structure CCW1 may be the upper surface 162_US of the second core separation pattern 162. Based on the bottom surface 105BS of the field insulating film 105, the upper surface CCW1_US of the first channel separation structure CCW1 may be lower in the first region CCW1_R1 than in the second region CCW1_R2. The upper surface 162_US of the second core separation pattern 162 may be on the same plane as the upper surface GCS_US of the gate separation structure GCS. In other words, the upper surface 162_US of the second core separation pattern 162 may be on the same plane as the upper surfaces 145US of the first gate capping patterns 145.

For example, FIG. 9 is a plan view taken at the height level of the second core separation pattern 162 in the second region CCW1_R2 of the first channel separation structure CCW1. FIGS. 10 and 11 are plan views taken at the height level of the first core separation pattern 161 in the second region CCW1_R2 of the first channel separation structure CCW1.

Referring to FIG. 9, a width W11 of the first channel separation structure CCW1 in the second direction DR2 between the first gate structures GS1 and the second gate structures GS2 may differ from a width W12 of the first channel separation structure CCW1 in the second direction DR2 between the first source/drain patterns 150 and the second source/drain patterns 250. For example, the width W11 of the first channel separation structure CCW1 in the second direction DR2 between the first gate structures GS1 and the second gate structures GS2 may be greater than the width W12 of the first channel separation structure CCW1 in the second direction DR2 between the first source/drain patterns 150 and the second source/drain patterns 250.

The first source/drain patterns 150 may overlap the first channel separation structure CCW1 in the first direction DR1 by a first overlapping width W13. The second source/drain patterns 250 may overlap the first channel separation structure CCW1 in the first direction DR1 by a second overlapping width W14.

For example, referring to FIG. 8, if the extension line of the first width centerline WCL1 is aligned with the second width centerline WCL2 in the third direction DR3, the first overlapping width W13 may be equal to the second overlapping width W14. As another example, if the extension line of the first width centerline WCL1 is misaligned with the second width centerline WCL2 in the third direction DR3, the first overlapping width W13 may differ from the second overlapping width W14.

Referring to FIG. 10, boundaries where the first source/drain patterns 150 are in contact with the first channel separation structure CCW1 may be aligned with boundaries where the first gate structures GS1 are in contact with the first channel separation structure CCW1 in the first direction DR1.

Referring to FIG. 11, the connecting liner separation patterns 163CP may be disposed between adjacent first source/drain patterns 150 in the first direction DR1. The connecting liner separation patterns 163CP may also be disposed between adjacent second source/drain patterns 250 in the first direction DR1.

A source/drain etching stop film 185 may extend along the outer sidewalls of the first gate spacers 140 and the outer sidewalls of the third gate spacers 340 and along the sidewalls of the first source/drain patterns 150, the sidewalls of the second source/drain patterns 250, the sidewalls of the third source/drain patterns 350, and the sidewalls of the fourth source/drain patterns 450. The source/drain etching stop film 185 may extend along the upper surface 105US of the field insulating film 105. For example, the source/drain etching stop film 185 may be in contact with the sidewalls of the first source/drain patterns 150, the sidewalls of the second source/drain patterns 250, the sidewalls of the third source/drain patterns 350, and the sidewalls of the fourth source/drain patterns 450.

Portions of the source/drain etching stop film 185 may extend along the sidewalls of the first channel separation structure CCW1 and the sidewalls of the second channel separation structure CCW2. The portions of the source/drain etching stop film 185 on the sidewalls of each of the first and second channel separation structures CCW1 and CCW2 may be remaining portions that are not removed during the process of forming the source/drain contacts (180, 280, 380, and 480).

The source/drain etching stop film 185 may include, for example, one of silicon nitride, silicon oxynitride, silicon oxycarbonitride, silicon boron nitride, silicon oxyboronitride, silicon oxycarbide, or a combination thereof.

If the source/drain etching stop film 185 includes the same material as the second core separation patterns 162 of the first and second channel separation structures CCW1 and CCW2, the boundary between the source/drain etching stop film 185 and the second core separation patterns 162 may not be distinguishable. In this case, the portions of the source/drain etching stop film 185 disposed on the first source/drain patterns 150, the second source/drain patterns 250, the third source/drain patterns 350, and the fourth source/drain patterns 450 and in contact with the first source/drain contacts 180, the second source/drain contacts 280, the third source/drain contacts 380, and the fourth source/drain contacts 480 may appear as portions of the first and/or second channel separation structures CCW1 and CCW2.

In some implementations, the source/drain etching stop film 185 is not present.

An upper interlayer insulating film 190 may be disposed on the first surface 100US of the first substrate 100. The upper interlayer insulating film 190 may be disposed on the source/drain etching stop film 185. The upper interlayer insulating film 190 may be disposed on the first source/drain patterns 150, the second source/drain patterns 250, the third source/drain patterns 350, and the fourth source/drain patterns 450.

The upper interlayer insulating film 190 may include, for example, at least one of silicon oxide, silicon nitride, silicon oxynitride, or a low-k material. The dielectric constant of the low-k material may be less than the dielectric constant of silicon oxide, which is 3.9.

The first source/drain contacts 180 may be disposed on the first source/drain patterns 150. The first source/drain contacts 180 are electrically connected to the first source/drain patterns 150. The first source/drain contacts 180 are disposed between the first channel separation structure CCW1 and the gate separation structure GCS.

The second source/drain contacts 280 may be disposed on the second source/drain patterns 250. The second source/drain contacts 280 are electrically connected to the second source/drain patterns 250. The second source/drain contacts 280 are disposed between the first channel separation structure CCW1 and the gate separation structure GCS.

The third source/drain contacts 380 may be disposed on the third source/drain patterns 350. The third source/drain contacts 380 may be electrically connected to the third source/drain patterns 350. The fourth source/drain contacts 480 may be disposed on the fourth source/drain patterns 450. The fourth source/drain contacts 480 are electrically connected to the fourth source/drain patterns 450.

The first contact silicide films 155 may be disposed between the first source/drain contacts 180 and the first source/drain patterns 150. Second contact silicide film 255 may be disposed between the second source/drain contacts 280 and the second source/drain patterns 250. Third contact silicide films 355 may be disposed between the third source/drain contacts 380 and the third source/drain patterns 350. Fourth contact silicide films 455 may be disposed between the fourth source/drain contacts 480 and the fourth source/drain patterns 450.

The first source/drain contacts 180, the second source/drain contacts 280, the third source/drain contacts 380, and the fourth source/drain contacts 480 are illustrated as having a single conductive film structure, but are not limited thereto. In some implementations, the first source/drain contacts 180, the second source/drain contacts 280, the third source/drain contacts 380, and the fourth source/drain contacts 480 may each have a multi-conductive film structure including a barrier film and a plug film. The first source/drain contacts 180, the second source/drain contacts 280, the third source/drain contacts 380, and the fourth source/drain contacts 480 may include, for example, at least one of a metal, a conductive metal nitride, a conductive metal carbide, a conductive metal oxide, a conductive metal carbonitride, or a two-dimensional (2D) material. The first contact silicide films 155, the second contact silicide films 255, the third contact silicide films 355, and the fourth contact silicide films 455 may include a metal silicide material.

The 2D material may include a 2D allotrope or a 2D compound and may include, for example, at least one of graphene, boron nitride (BN), molybdenum sulfide, molybdenum selenide, tungsten sulfide, tungsten selenide, or tantalum sulfide, but is not limited thereto. That is, the aforementioned 2D materials are merely examples, and other materials are within the scope of this disclosure.

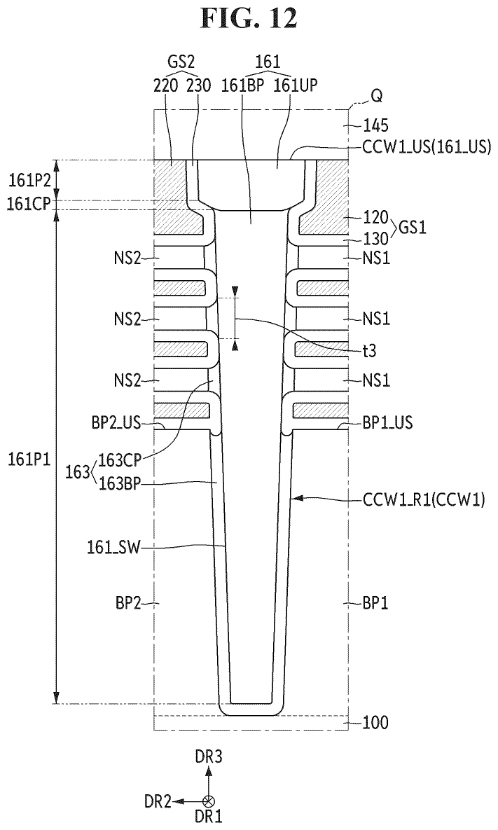

FIGS. 12 through 14 are cross-sectional views illustrating examples of semiconductor devices. For convenience of explanation, the focus will be on differences from what has been explained with reference to FIGS. 1 through 11.

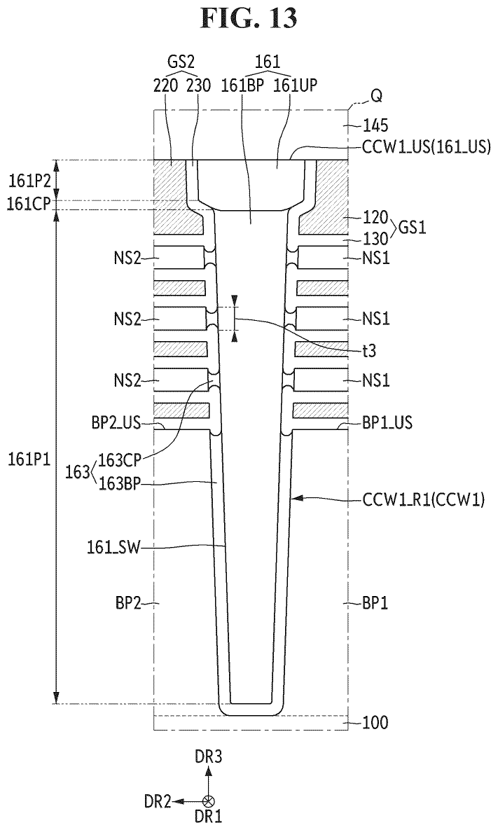

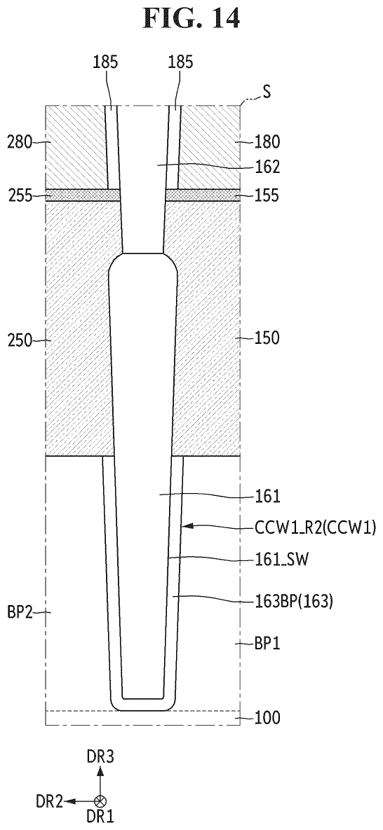

For reference, FIGS. 12 and 13 are enlarged views of portion Q of FIG. 4. FIG. 14 is an enlarged view of portion S of FIG. 5.

Referring to FIGS. 12 and 13, in some implementations, a thickness t3 of a liner separation pattern 163 in the third direction DR3 between a first core separation pattern 161 and first sheet patterns NS1, and between the first core separation pattern 161 and second sheet patterns NS2, may vary in a direction away from the first sheet patterns NS1 and the second sheet patterns NS2.

Referring to FIG. 12, the thickness t3 of the liner separation pattern 163 in the third direction DR3 between the first core separation pattern 161 and the first sheet patterns NS1, and between the first core separation pattern 161 and the second sheet patterns NS2, may increase in the direction away from the first sheet patterns NS1 and the second sheet patterns NS2.

Referring to FIG. 13, the thickness t3 of the liner separation pattern 163 in the third direction DR3 between the first core separation pattern 161 and the first sheet patterns NS1, and between the first core separation pattern 161 and the second sheet patterns NS2, may decrease and then increase in the direction away from the first sheet patterns NS1 and the second sheet patterns NS2.

Referring to FIG. 14, in a second region CCW1_R2 of a first channel separation structure CCW1, the width of the first core separation pattern 161 in the second direction DR2 may increase and then decrease in a direction away from a bottom surface 105BS of a field insulating film 105.

The slope of sidewalls 161_SW of the first core separation pattern 161 may change.

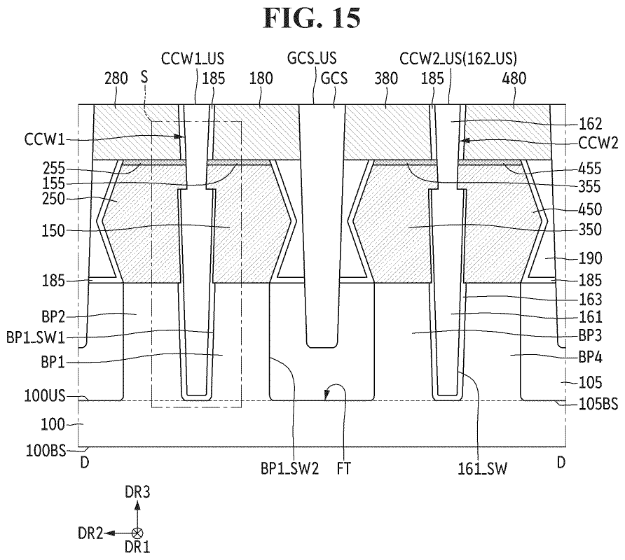

FIGS. 15 through 18 are diagrams for explaining an example of a semiconductor device. For convenience of explanation, the focus will be on differences from what has been explained with reference to FIGS. 1 through 11.

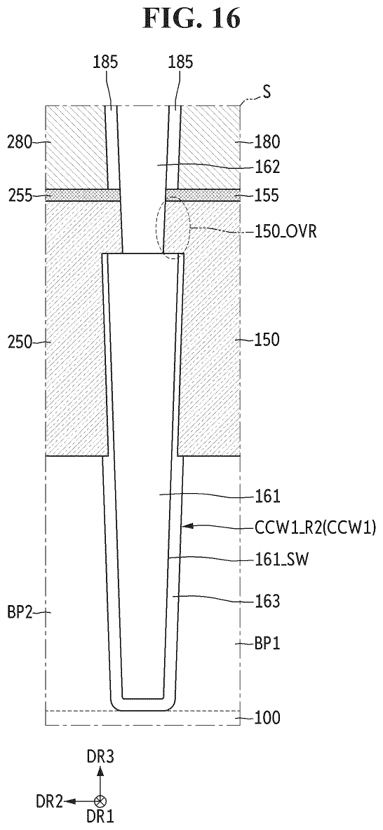

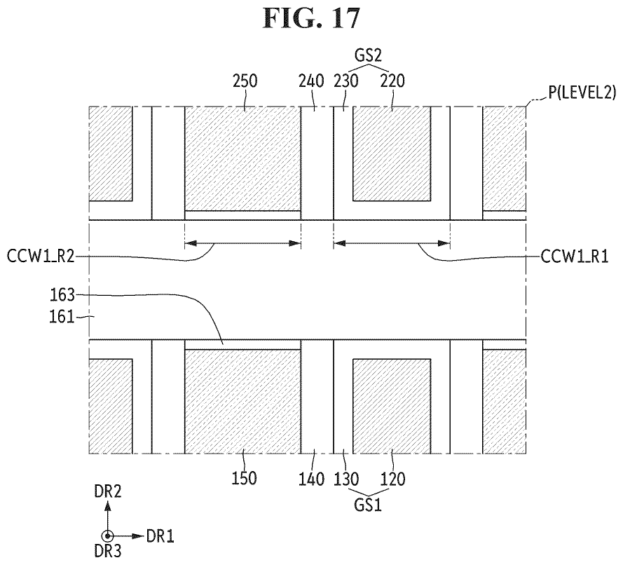

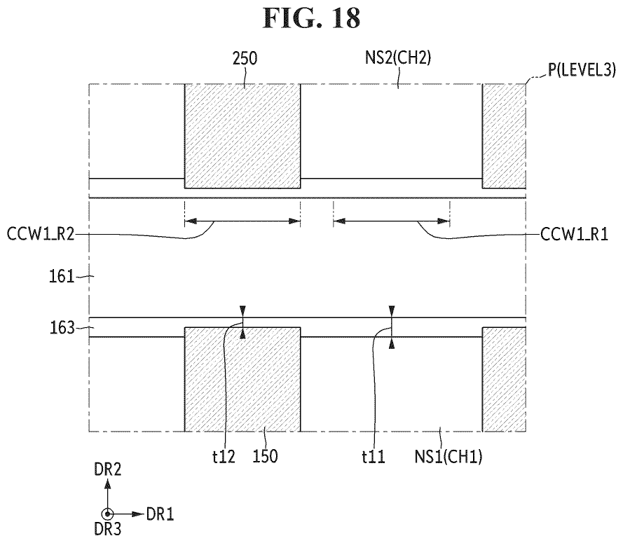

For reference, FIG. 16 is an enlarged view of portion S of FIG. 15. FIGS. 17 and 18 are plan views taken at the height level of the first core separation pattern 161 in the second region CCW1_R2 of the first channel separation structure CCW1.

Referring to FIGS. 15 through 18, in some implementations, a liner separation pattern 163 of a first channel separation structure CCW1 may be disposed along the boundaries between the first channel separation structure CCW1 and a first source/drain pattern 150, and along the boundary between the first channel separation structure CCW1 and a second source/drain pattern 250.

A liner separation pattern 163 of a second channel separation structure CCW2 may also be disposed along the boundary between the second channel separation structure CCW2 and a third source/drain pattern 350, and along the boundary between the second channel separation structure CCW2 and a fourth source/drain pattern 450.

In the second region CCW1_R2 of the first channel separation structure CCW1, the liner separation pattern 163 of the first channel separation structure CCW1 may extend along the boundary between the first core separation pattern 161 and the first source/drain pattern 150, and along the boundary between the first core separation pattern 161 and the second source/drain pattern 250. The liner separation pattern 163 may not be disposed along the boundary between a second core separation pattern 162 and the first source/drain pattern 150, and/or along the boundary between the second core separation pattern 162 and the second source/drain pattern 250.

Referring to FIG. 18, the liner separation pattern 163 may be disposed between the first core separation pattern 161 and the first source/drain pattern 150, and between the first core separation pattern 161 and the first sheet pattern NS1. The liner separation pattern 163 may also be disposed between the first core separation pattern 161 and the second source/drain pattern 250, and between the first core separation pattern 161 and second sheet patterns NS2.

A thickness t11 of the liner separation pattern 163 in the second direction DR2 between the first core separation pattern 161 and first sheet patterns NS1 may differ from a thickness t12 of the liner separation pattern 163 in the second direction DR2 between the first core separation pattern 161 and the first source/drain pattern 150. The thickness t11 of the liner separation pattern 163 between the first core separation pattern 161 and the first sheet patterns NS1 may be greater than the thickness t12 of the liner separation pattern 163 between the first core separation pattern 161 and the first source/drain pattern 150.

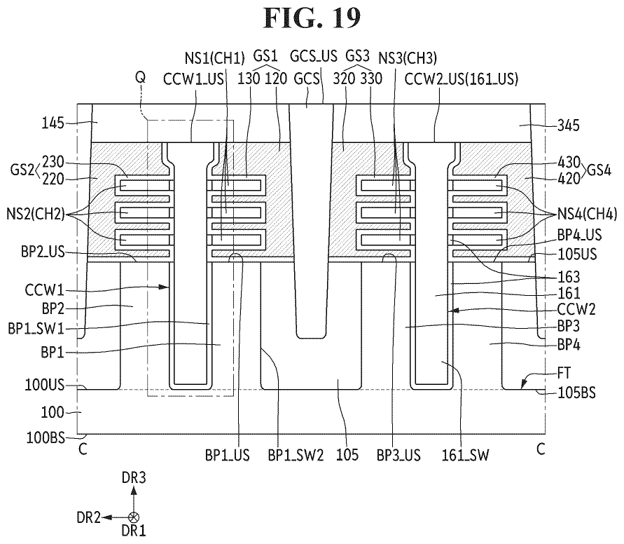

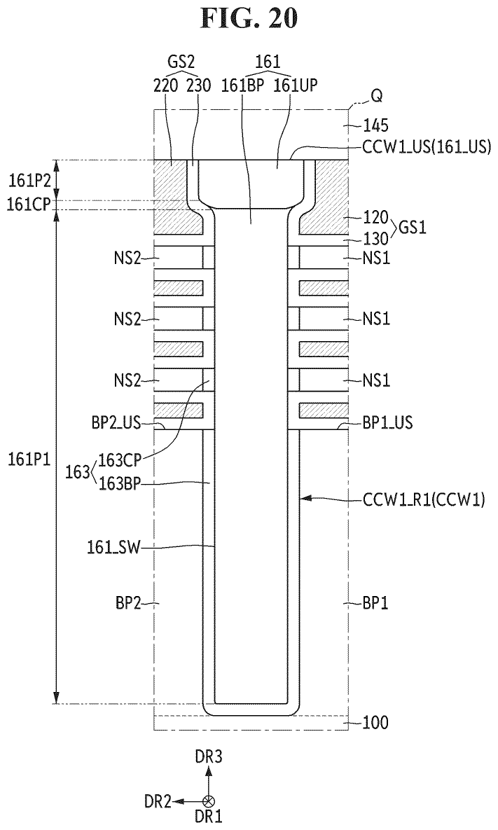

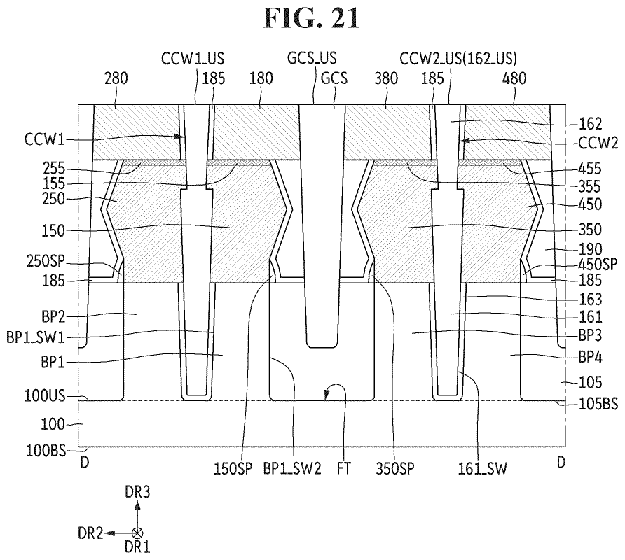

FIGS. 19 and 20 cross-sectional views illustrating an example of a semiconductor device. FIGS. 21 through 23 are cross-sectional views illustrating examples of semiconductor devices. For convenience of explanation, the focus will be on differences from what has been explained with reference to FIGS. 1 through 11. For reference, FIG. 20 is an enlarged view of portion Q of FIG. 19.

Referring to FIGS. 19 and 20, in a second portion 161P2 of a first core separation pattern 161 of a first channel separation structure CCW1, the width of the first core separation pattern 161 in the second direction DR2 may remain constant along a direction away from a bottom surface 105BS of a field insulating film 105.

In a first portion 161P1 of the first core separation pattern 161, the width of the first core separation pattern 161 in the second direction DR2 may remain constant along the direction away from the bottom surface 105BS of the field insulating film 105. For example, in the first portion 161P1 of the first core separation pattern 161, the distance between opposite sidewalls 161_SW of the first core separation pattern 161 in the second direction DR2 may remain constant.

Referring to FIG. 21, the semiconductor device may further include first, second, third, and fourth source/drain fences 150SP, 250SP, 350SP, and 450SP disposed on an upper surface 105US of a field insulating film 105.

The first, second, third, and fourth source/drain fences 150SP, 250SP, 350SP, and 450SP may each protrude in the third direction DR3 from or over the upper surface 105US of the field insulating film 105. The first, second, third, and fourth source/drain fences 150SP, 250SP, 350SP, and 450SP may be in contact with first, second, third, and fourth source/drain patterns 150, 250, 350, and 450, respectively.

The first source/drain fence 150SP may be disposed on a portion of the sidewall of the first source/drain pattern 150. The second source/drain fence 250SP may be disposed on a portion of the sidewall of the second source/drain pattern 250. The third source/drain fence 350SP may be disposed on a portion of the sidewall of the third source/drain pattern 350. The fourth source/drain fence 450SP may be disposed on a portion of the sidewall of the fourth source/drain pattern 450.

The first, second, third, and fourth source/drain fences 150SP, 250SP, 350SP, and 450SP may include an insulating material included in first and third gate spacers 140 and 340. For example, in a manufacturing process, the first, second, third, and fourth source/drain fences 150SP, 250SP, 350SP, and 450SP may be formed in the same manner as the first and third gate spacers 140 and 340.

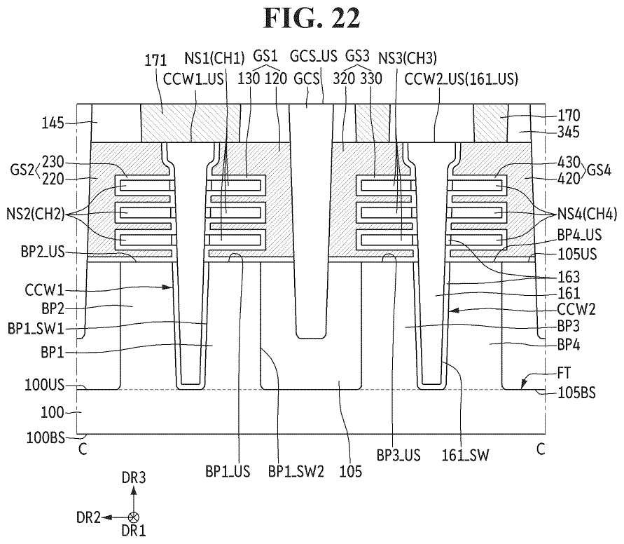

Referring to FIG. 22, the semiconductor device may further include gate contacts 170 and a gate bridge contact 171.

The gate contacts 170 may be disposed in a second gate capping pattern 345. The gate contacts 170 may be connected to third and fourth gate electrodes 320 and 420, respectively. For example, a single gate contact 170 may be connected to one gate electrode 340 or 440.

The gate bridge contact 171 may be disposed in a first gate capping pattern 145. The gate bridge contact 171 may be connected to first and second gate electrodes 120 and 220. The gate bridge contact 171 may connect the first gate and second electrodes 120 and 220, which are spaced apart in the second direction DR2. The gate bridge contact 171 may serve to connect a pair of spaced gate electrodes and also serve the same function as the gate contacts 170.

The gate contacts 170 and the gate bridge contact 171 are illustrated as having a single conductive film structure, but are not limited thereto. For example, the gate contacts 170 and the gate bridge contact 171 may each have a multi-conductive film structure including a barrier film and a plug film. The gate contacts 170 and the gate bridge contact 171 may include, for example, at least one of a metal, a conductive metal nitride, a conductive metal carbide, a conductive metal oxide, a conductive metal carbonitride, or a 2D material.

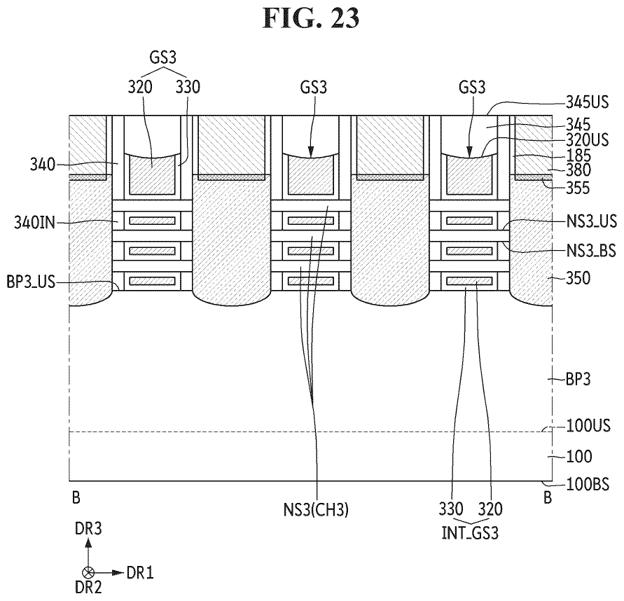

Referring to FIG. 23, the semiconductor device may further include inner spacers 340 IN disposed between third source/drain patterns 350 and third inner gate structures INT_GS 3.

The inner spacers 340 IN may be disposed between a third lower pattern BP3 and third sheet patterns NS3, and between adjacent third sheet patterns NS3 in the third direction DR3. The third inner gate structures INT_GS3 may not be in contact with the third source/drain patterns 350.

The inner spacers 340 IN may include, for example, one of silicon nitride, silicon oxynitride, silicon oxide, silicon oxycarbonitride, silicon boron nitride, silicon oxyboronitride, silicon oxycarbide, or a combination thereof.

In some implementations, the inner spacers 340 IN may be disposed between a first lower pattern (BP1 in FIG. 2) and first sheet patterns NS1, and between adjacent first sheet patterns NS1 in the third direction DR3. As another example, the inner spacers 340 IN may not be disposed between the first lower pattern BP1 and the first sheet patterns NS1, or between the adjacent first sheet patterns NS1 in the third direction DR3.

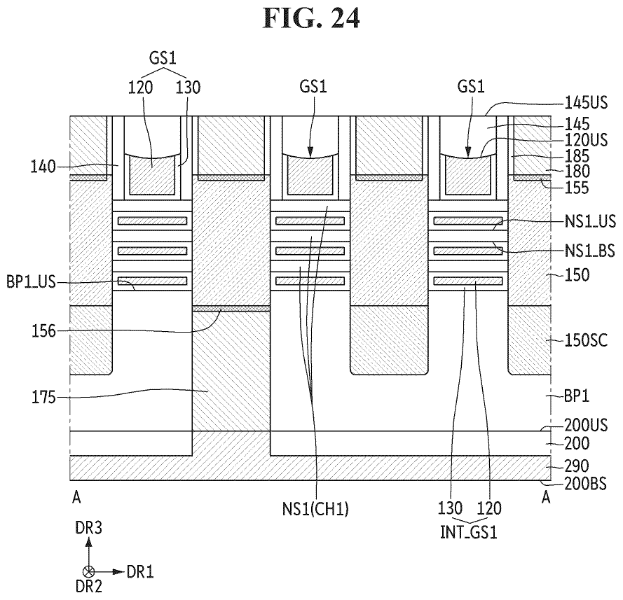

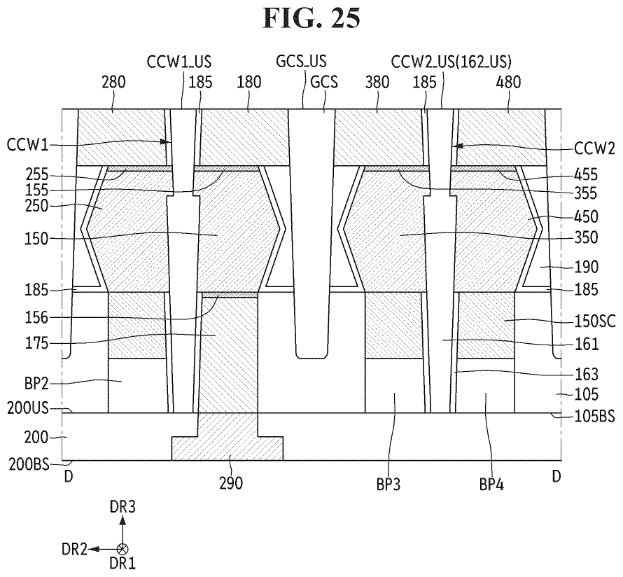

FIGS. 24 and 25 are cross-sectional views illustrating an example of a semiconductor device. For convenience of explanation, the focus will be on differences from what has been explained with reference to FIGS. 1 through 23.

Referring to FIGS. 24 and 25, the semiconductor device may further include sacrificial semiconductor patterns 150SC, a backside source/drain contact 175, and a backside wiring line 290.

First, second, third, and fourth lower patterns BP1, BP2, BP3, and BP4 may be disposed on a second substrate 200. The second substrate 200 may include a first surface 200US and a second surface 200BS, which are opposite to each other in the third direction DR3. The first, second, third, and fourth lower patterns BP1, BP2, BP3, and BP4 may be disposed on the first surface 200US of the second substrate 200.

The second substrate 200 may include an insulating material, and may include at least one of silicon oxide, silicon nitride, or a combination thereof. The second substrate 200 may be a substrate formed by a deposition process after the removal of the first substrate 100 of FIGS. 2 through 5.

A field insulating film 105 may be in contact with the second substrate 200. A bottom surface 105BS of the field insulating film 105 faces the second substrate 200.

The sacrificial semiconductor patterns 150SC may be disposed on the second substrate 200. The sacrificial semiconductor patterns 150SC may be disposed within the first, second, third, and fourth lower patterns BP1, BP2, BP3, and BP4. The sacrificial semiconductor patterns 150SC may be disposed between the second substrate 200 and first source/drain patterns 150, second source/drain patterns 250, third source/drain patterns 350, and fourth source/drain patterns 450. The sacrificial semiconductor patterns 150SC may overlap the first source/drain patterns 150, the second source/drain patterns 250, the third source/drain patterns 350, and the fourth source/drain patterns 450 in the third direction DR3.

The sacrificial semiconductor patterns 150SC may include a material having an etching selectivity with respect to the first, second, third, and fourth lower patterns BP1, BP2, BP3, and BP4. When the first, second, third, and fourth lower patterns BP1, BP2, BP3, and BP4 are Si patterns, the sacrificial semiconductor patterns 150SC may include SiGe.

The backside wiring line 290 may be disposed within the second substrate 200. The backside wiring line 290 may include a line portion and a via portion. The line portion of the backside wiring line 290 is illustrated as extending in the first direction DR1, but is not limited thereto. The via portion of the backside wiring line 290 may protrude from the line portion in the third direction DR3. In some implementations, the backside wiring line 290 may not include a via portion.

For example, the backside wiring line 290 may be a power line that supplies power to the semiconductor device. As another example, the backside wiring line 290 may be a signal line that supplies an operation signal to the semiconductor device.

The backside source/drain contact 175 may be disposed between the first source/drain patterns 150 and the backside wiring line 290. The backside source/drain contact 175 electrically connects the first source/drain patterns 150 and the backside wiring line 290.

The backside source/drain contact 175 is illustrated as being connected to some of the first source/drain patterns 150, but is not limited thereto. For example, the backside source/drain contact 175 may be connected to the second source/drain patterns 250, the third source/drain patterns 350, and/or the fourth source/drain patterns 450.

A backside contact silicide film 156 may be disposed between the backside source/drain contact 175 and the first source/drain patterns 150.

The backside source/drain contact 175 and the backside wiring line 290 are illustrated as each having a single conductive film, but are not limited thereto. For example, at least one of the backside source/drain contact 175 and the backside wiring line 290 may have a multi-conductive film structure including a barrier film and a filling film. The backside source/drain contact 175 and the backside wiring line 290 may each include, for example, at least one of a metal, a conductive metal nitride, a conductive metal carbide, a conductive metal oxide, a conductive metal carbonitride, or a 2D material.

In some implementations, a backside contact liner may be disposed between the backside source/drain contact 175 and the first lower pattern BP1. The backside contact liner may include an insulating material.

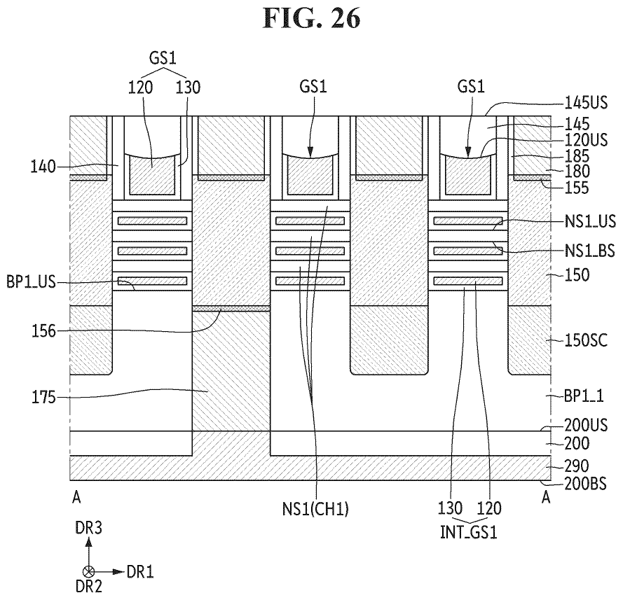

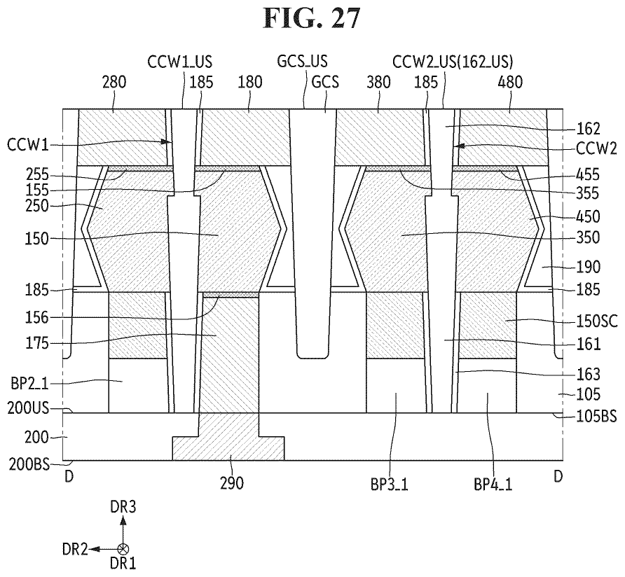

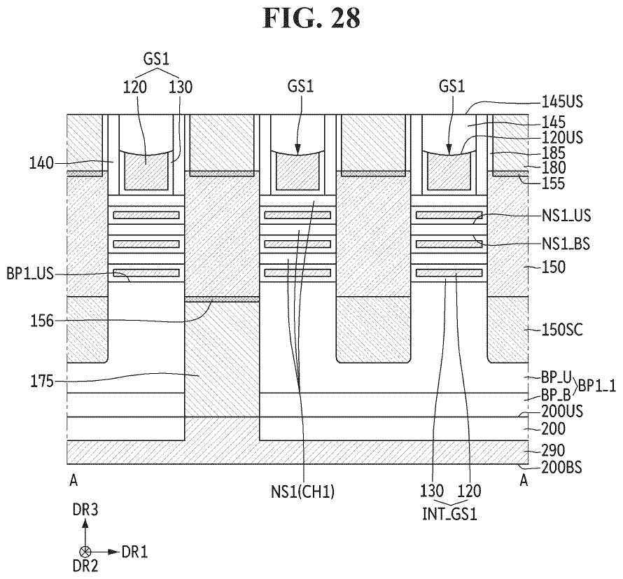

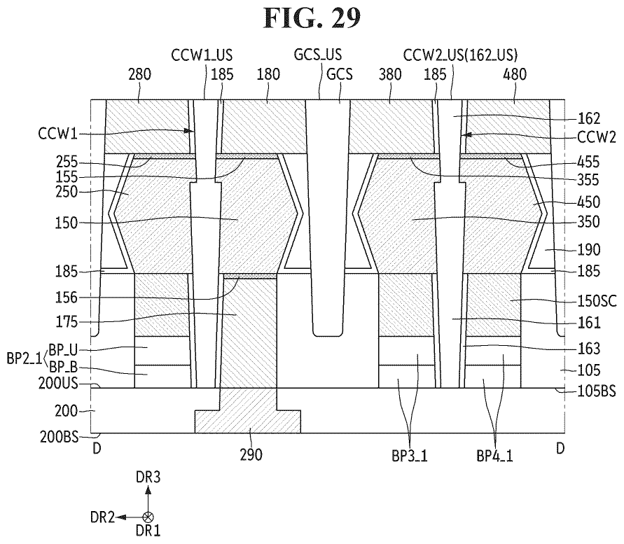

FIGS. 26 and 27 are cross-sectional views illustrating an example of a semiconductor device. FIGS. 28 and 29 are cross-sectional views illustrating an example of a semiconductor device. For convenience of explanation, the focus will be on differences from what has been explained with reference to FIGS. 24 and 25.

Referring to FIGS. 26 and 27, in some implementations, first, second, third, and fourth lower patterns BP1_1, BP2_1, BP3_1, and BP4_1 may each include an insulating material.

The first, second, third, and fourth lower patterns BP1_1, BP2_1, BP3_1, and BP4_1 may include at least one of silicon oxide, silicon nitride, or silicon oxynitride. When the first, second, third, and fourth lower patterns BP1_1, BP2_1, BP3_1, and BP4_1 include the same insulating material as a field insulating film 105, the boundaries between the field insulating film 105 and the first, second, third, and fourth lower patterns BP1_1, BP2_1, BP3_1, and BP4_1 may not be distinguishable.

Referring to FIGS. 28 and 29, in some implementations, first, second, third, and fourth lower patterns BP1_1, BP2_1, BP3_1, and BP4_1 may each include a first sub-lower pattern BP_B and a second sub-lower pattern BP_U.

The first sub-lower pattern BP_B may be disposed between the second sub-lower pattern BP_U and a backside wiring line 290.

The first sub-lower pattern BP_B may include an insulating material. The second sub-lower pattern BP_U may include a semiconductor material.

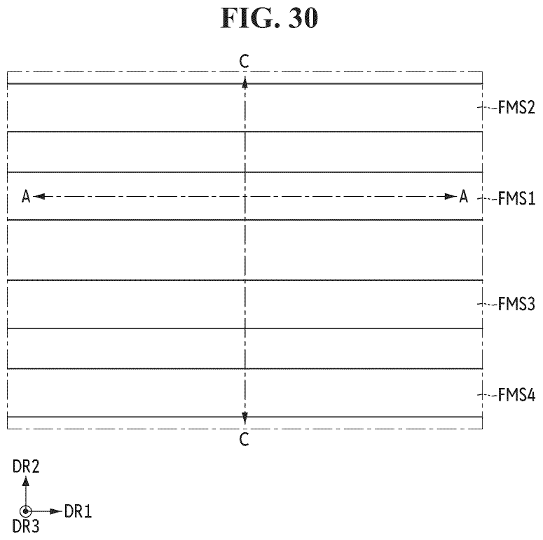

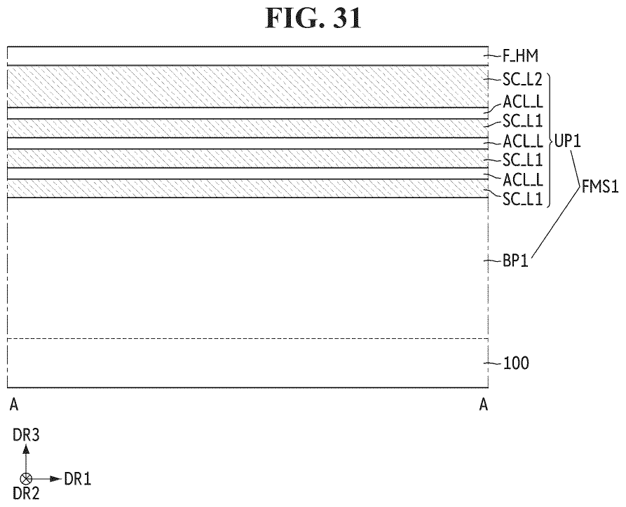

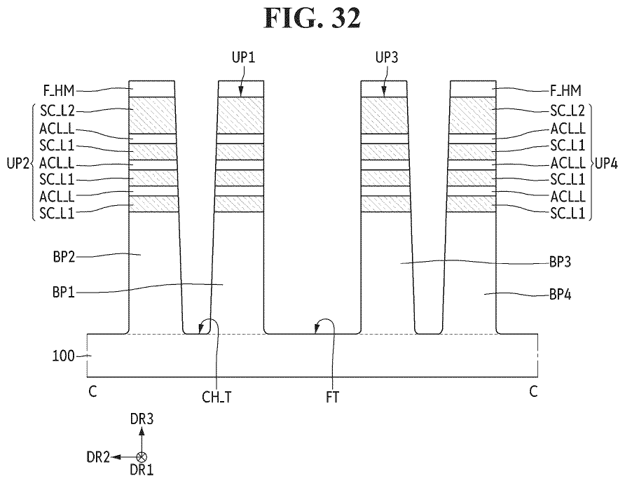

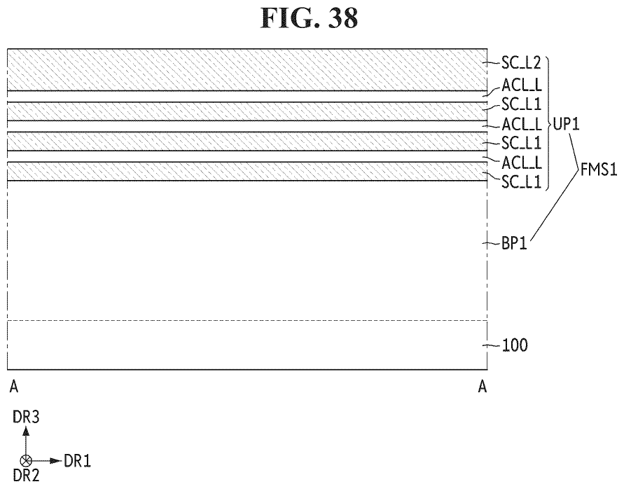

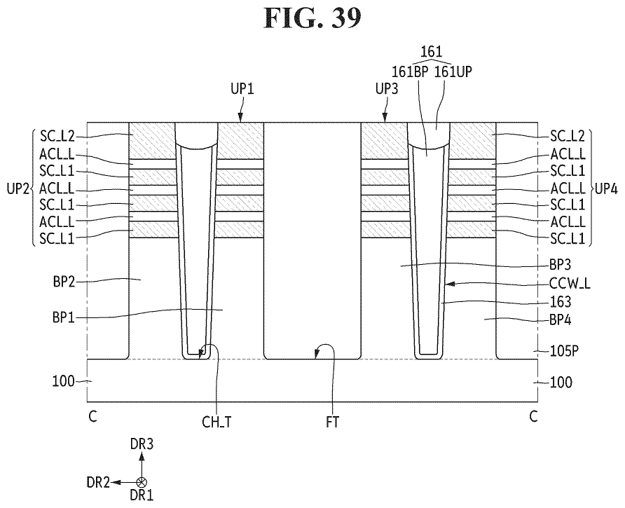

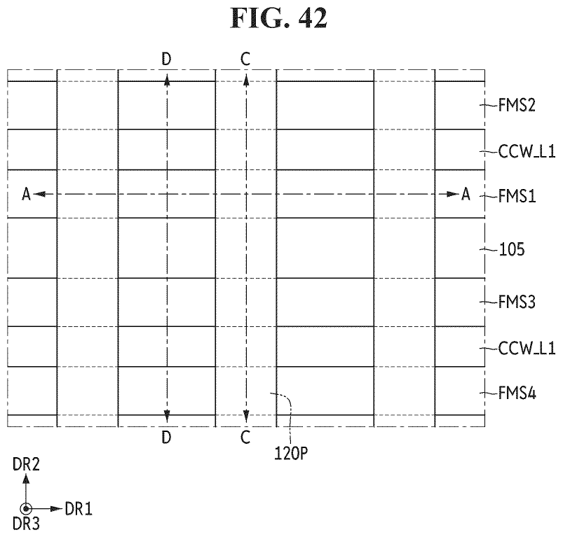

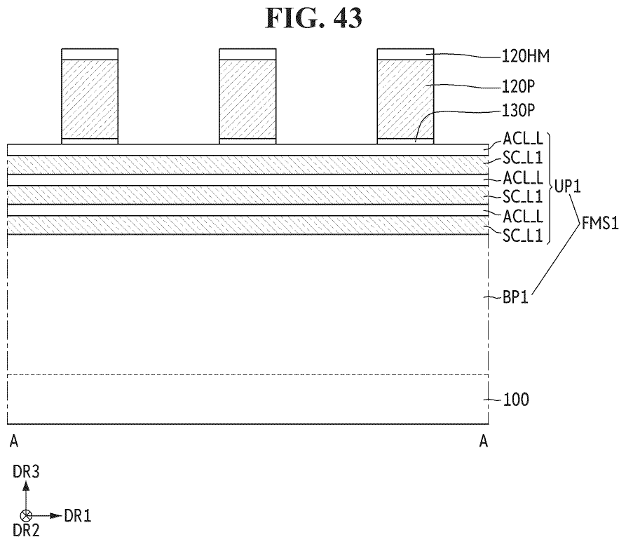

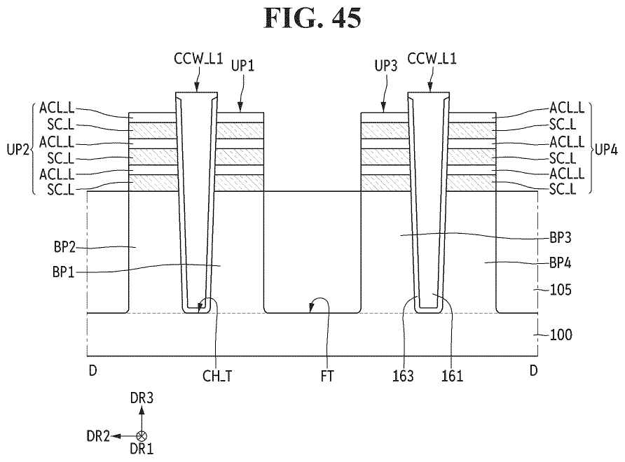

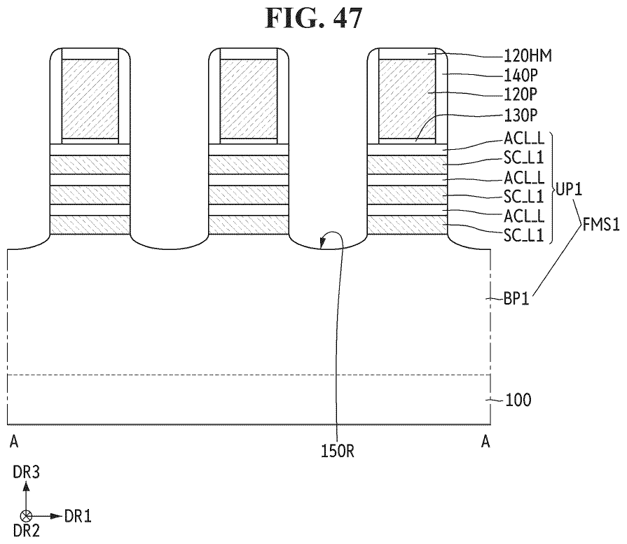

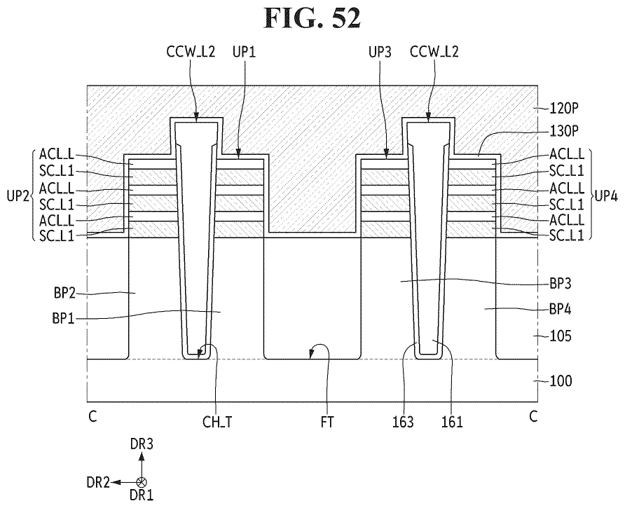

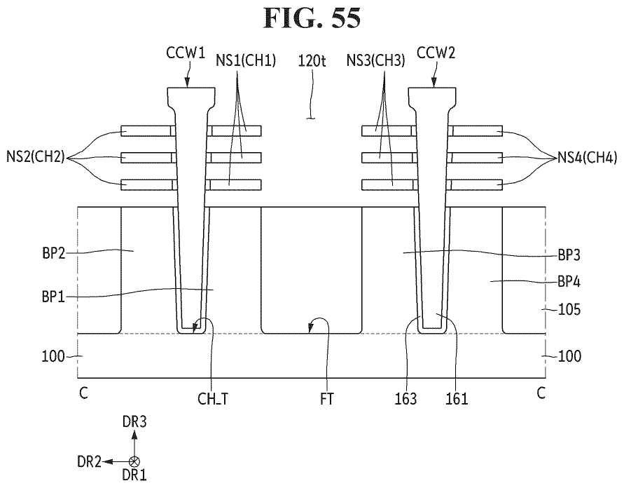

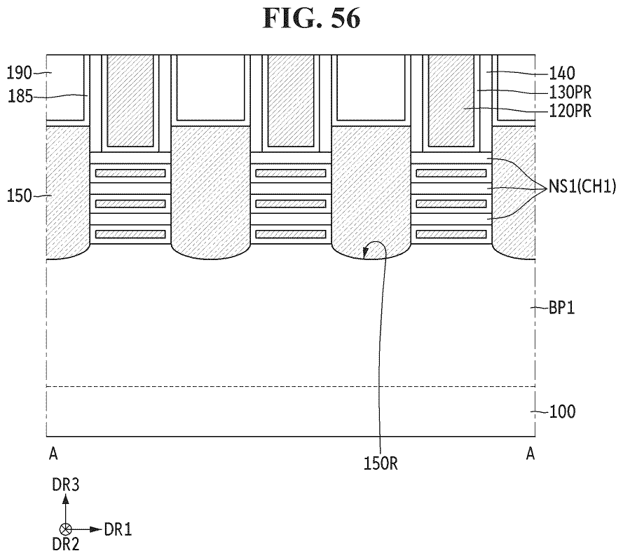

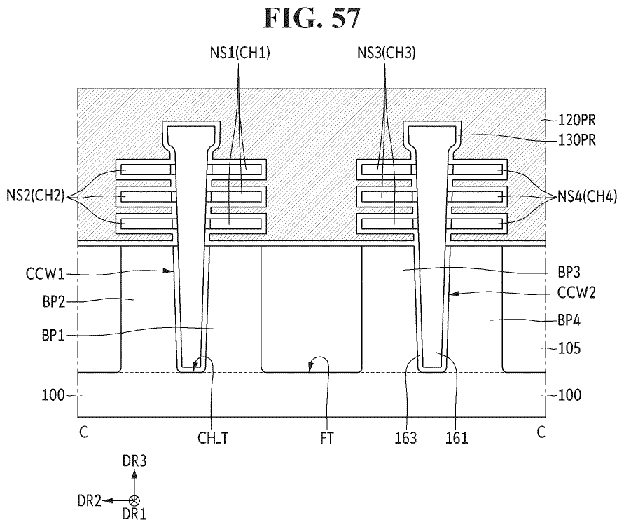

FIGS. 30 through 57 are diagrams illustrating stages of an example of a method for manufacturing a semiconductor device. For example, the disclosed method, or portions thereof, can be used to manufacture the semiconductor devices described with respect to FIGS. 1 to 29.

Referring to FIGS. 30 through 32, first, second, third, and fourth mold fin-shaped patterns FMS1, FMS2, FMS3, and FMS4 may be formed on a first substrate 100.

The first, second, third, and fourth mold fin-shaped patterns FMS1, FMS2, FMS3, and FMS4 may each extend in the first direction DR1. The first, second, third, and fourth mold fin-shaped patterns FMS1, FMS2, FMS3, and FMS4 may be spaced apart from each other in the second direction DR2.

The first and second mold fin-shaped patterns FMS1 and FMS2 may be separated by a channel trench CH_T extending in the first direction DR1. The third and fourth mold fin-shaped patterns FMS3 and FMS4 may also be separated by a channel trench CH_T extending in the first direction DR1. The first and third mold fin-shaped patterns FMS1 and FMS3 may be separated by a fin trench FT extending in the first direction DR1.

Two mold fin-shaped patterns may be formed between a pair of adjacent fin trenches FT in the second direction DR2, and may be separated by a channel trench CH_T. The bottom surfaces of the channel trenches CH_T are illustrated as being disposed at the same height level as the bottom surfaces of the fin trenches FT, but are not limited thereto. For example, the bottom surfaces of the channel trenches CH_T may be disposed lower than the bottom surfaces of the fin trenches FT.

The first mold fin-shaped pattern FMS1 may include a first lower pattern BP1 and a first upper pattern structure UP1. The second mold fin-shaped pattern FMS2 may include a second lower pattern BP2 and a second upper pattern structure UP2. The third mold fin-shaped pattern FMS3 may include a third lower pattern BP3 and a third upper pattern structure UP3. The fourth mold fin-shaped pattern FMS4 may include a fourth lower pattern BP4 and a fourth upper pattern structure UP4. The first, second, third, and fourth upper pattern structures UP1, UP2, UP3, and UP4 may be formed on the first, second, third, and fourth lower patterns BP1, BP2, BP3, and BP4, respectively.

The first, second, third, and fourth upper pattern structures UP1, UP2, UP3, and UP4 may each include a plurality of sacrificial patterns (SC_L1 and SC_L2) and active patterns ACL_L that are alternately stacked. The sacrificial patterns (SC_L1 and SC_L2) included in each of the first, second, third, and fourth upper pattern structures UP1, UP2, UP3, and UP4 may include a plurality of first sacrificial patterns SC_L1 and a second sacrificial pattern SC_L2. In each of the first, second, third, and fourth upper pattern structures UP1, UP2, UP3, and UP4, the first sacrificial patterns SC_L1 and the active patterns ACL_L may be alternately stacked. The second sacrificial pattern SC_L2 may be disposed at the top of each of the first, second, third, and fourth upper pattern structures UP1, UP2, UP3, and UP4. For example, the active patterns ACL_L may include crystalline silicon films. The first sacrificial patterns SC_L1 may include crystalline SiGe films. The second sacrificial pattern SC_L2 may include a material having an etching selectivity with respect to silicon oxide, crystalline Si, and crystalline SiGe. Additionally, the second sacrificial pattern SC_L2 may include a material having an etching selectivity with respect to the insulating material included in first core separation patterns (161 in FIG. 4) and/or other portions of the channel separation structure, such as the pre-separation liner film 163P. For example, the second sacrificial pattern SC_L2 may include an amorphous SiGe film doped with a high concentration of impurities, but is not limited thereto.

For example, the second sacrificial pattern SC_L2 may be thicker than the first sacrificial patterns SC_L1.

Mold hard mask patterns F_HM may be disposed on each of the first, second, third, and fourth mold fin-shaped patterns FMS1, FMS2, FMS3, and FMS4. The mold hard mask patterns F_HM may be used as a mask for forming the first, second, third, and fourth mold fin-shaped patterns FMS1, FMS2, FMS3, and FMS4. For example, the mold hard mask patterns F_HM may include silicon nitride, but are not limited thereto.

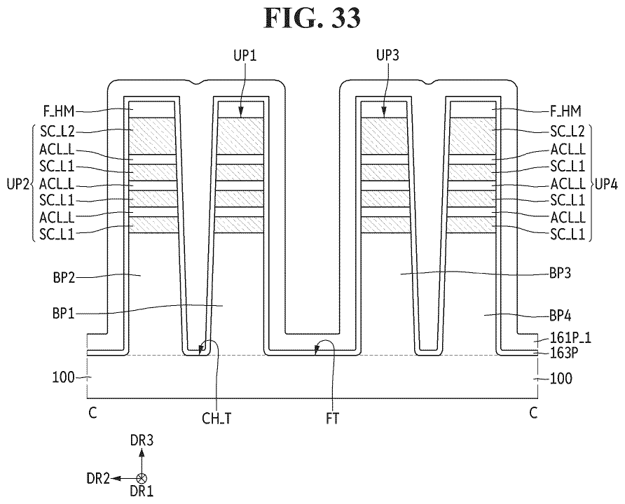

Referring to FIG. 33, a pre-separation liner film 163P may be formed along the profiles of the first, second, third, and fourth mold fin-shaped patterns FMS1, FMS2, FMS3, and FMS4 and along the upper surface of the first substrate 100.

The pre-separation liner film 163P may be formed along the sidewalls and bottom surfaces of the channel trenches CH_T and the sidewalls and bottom surfaces of the fin trenches FT. The pre-separation liner film 163P may include, for example, silicon oxide.

A first pre-core separation film 161P_1 may be formed on the pre-separation liner film 163P. The first pre-core separation film 161P_1 may fill the channel trenches CH_T. The first pre-core separation film 161P_1 may be formed along the sidewalls and bottom surfaces of the fin trenches FT. The first pre-core separation film 161P_1 may be formed on the mold hard mask patterns F_HM.

The first pre-core separation film 161P_1 may include a material having an etching selectivity with respect to the material of the pre-separation liner film 163P, e.g., silicon oxide. For example, the first pre-core separation film 161P_1 may include silicon nitride, silicon oxynitride, silicon oxycarbonitride, silicon boron nitride, silicon oxyboronitride, silicon oxycarbide (SiOC), or a combination thereof.

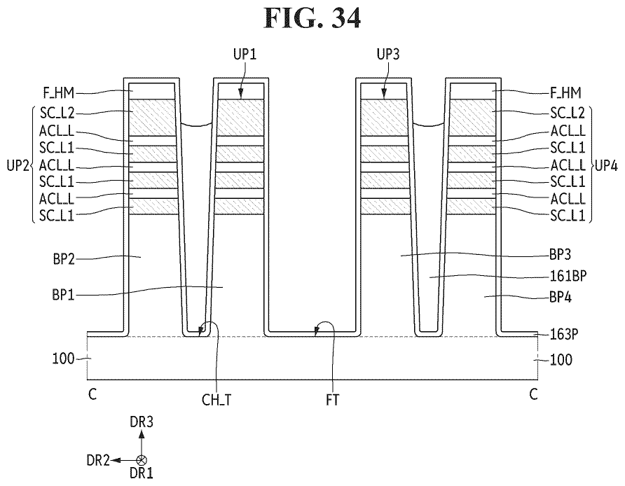

Referring to FIGS. 33 and 34, lower core separation patterns 161BP may be formed within the channel trenches CH_T by removing portions of the first pre-core separation film 161P_1.

The lower core separation patterns 161BP may fill portions of the channel trenches CH_T. During the formation of the lower core separation patterns 161BP, portions of the first pre-core separation film 161P_1 on the sidewalls and bottom surfaces of the fin trenches FT may be removed. Additionally, portions of the first pre-core separation film 161P_1 on the mold hard mask patterns F_HM may also be removed.

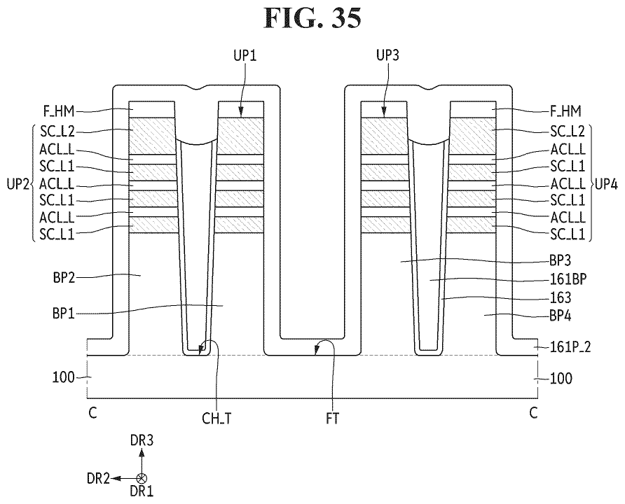

Referring to FIGS. 34 and 35, liner separation patterns 163 may be formed along the sidewalls and bottom surfaces of the channel trenches CH_T by removing portions of the pre-separation liner film 163P.

Portions of the pre-separation liner film 163P not covered by the lower core separation patterns 161BP may be removed, thereby forming the liner separation patterns 163. Portions of the pre-separation liner film 163P formed along the sidewalls and bottom surfaces of the fin trenches FT may be removed. Portions of the pre-separation liner film 163P on the mold hard mask patterns F_HM may be removed. The lower core separation patterns 161BP and the liner separation patterns 163 may be included in first pre-lower channel separation structures. The first pre-lower channel separation structures may fill portions of the channel trenches CH_T.

Thereafter, a second pre-core separation film 161P_2 may be formed on the lower core separation patterns 161BP and the liner separation patterns 163.

The second pre-core separation film 161P_2 may fill the channel trenches CH_T. The second pre-core separation film 161P_2 may be formed along the sidewalls and bottom surfaces of the fin trenches FT. The second pre-core separation film 161P_2 may be formed on the mold hard mask patterns F_HM.

The second pre-core separation film 161P_2 may include a material having an etching selectivity with respect to the material of the linear separation patterns 163, e.g., silicon oxide. For example, the second pre-core separation film 161P_2 may include silicon nitride, silicon oxynitride, silicon oxycarbonitride, silicon boron nitride, silicon oxyboronitride, SiOC, or a combination thereof.

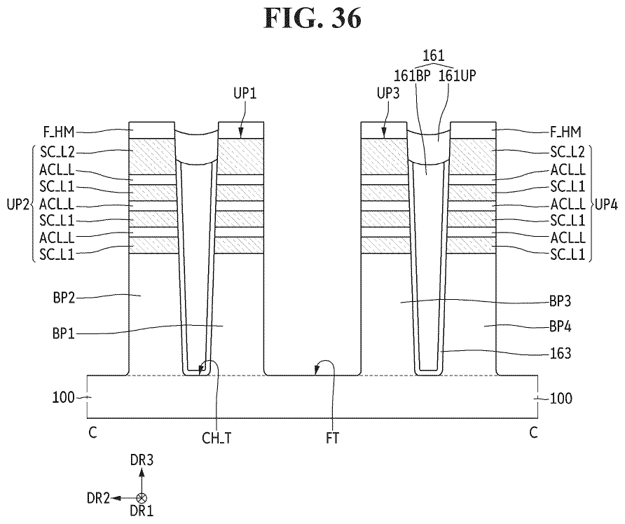

Referring to FIGS. 35 and 36, upper core separation patterns 161UP that fill the remaining portions of the channel trenches CH_T may be formed by removing portions of the second pre-core separation film 161P_2.

The upper core separation patterns 161UP may be formed on the lower core separation pattern s161BP and the liner separation patterns 163. The upper core separation patterns 161UP may serve as second pre-lower channel separation structures.

Thus, first core separation patterns 161, including the upper core separation patterns 161UP and the lower core separation patterns 161BP, may be formed within the channel trenches CH_T.

During the formation of the upper core separation patterns 161UP, portions of the second pre-core separation film 161P_2 on the sidewalls and bottom surfaces of the fin trenches FT may be removed. Additionally, portions of the second pre-core separation film 161P_2 on the mold hard mask patterns F_HM may also be removed.

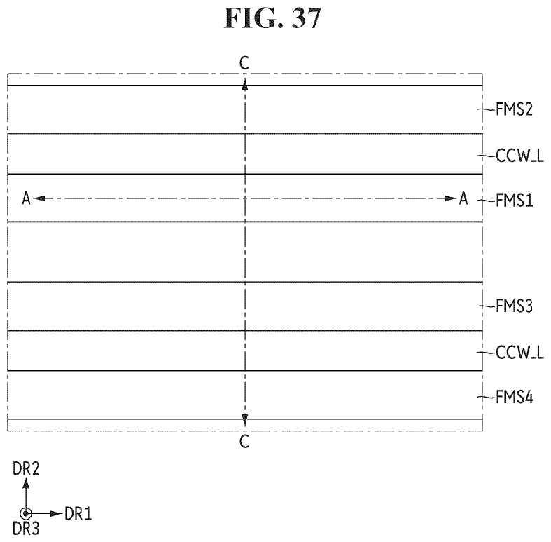

Referring to FIGS. 37 through 39, a pre-interlayer insulating film 105P may be formed on the first substrate 100.

The pre-interlayer insulating film 105P may fill the fin trenches FT. During the formation of the pre-interlayer insulating film 105P, the mold hard mask patterns F_HM on the first, second, third, and fourth mold fin-shaped patterns FMS1, FMS2, FMS3, and FMS4 may be removed. The upper surfaces of the first, second, third, and fourth upper pattern structures UP1, UP2, UP3, and UP4 may be exposed.

During the formation of the pre-interlayer insulating film 105P, lower channel separation structures CCW_L may be formed within the channel trenches CH_T. The lower channel separation structures CCW_L may include the first core separation patterns 161 and the liner separation patterns 163.

Referring to FIGS. 37 through 40, portions of the pre-interlayer insulating film 105P may be removed, thereby forming a field insulating film 105 on the first substrate 100.

The field insulating film 105 may fill portions of the fin trenches FT.

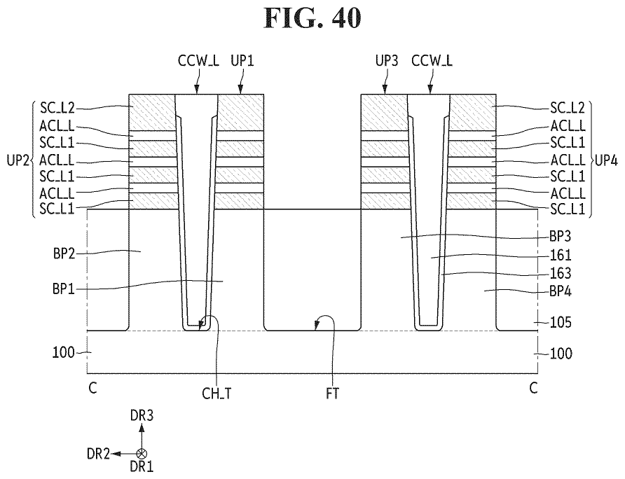

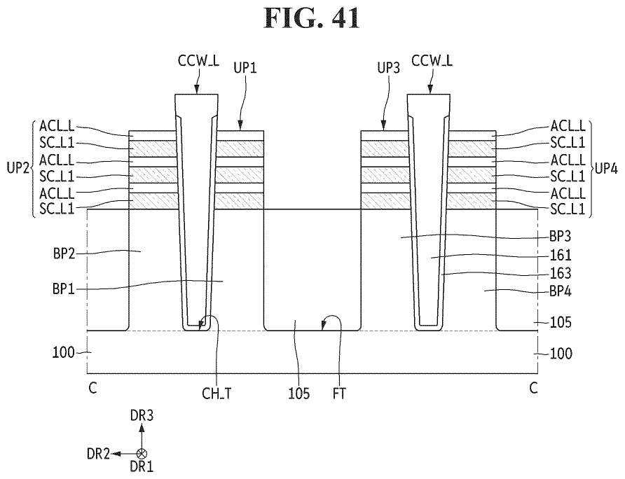

Referring to FIGS. 40 and 41, the second sacrificial pattern SC_L2 may be removed.

Portions of the lower channel separation structures CCW_L may protrude in the third direction DR3 beyond the first, second, third, and fourth upper pattern structures UP1, UP2, UP3, and UP4.

Referring to FIGS. 41 through 45, a plurality of dummy gate electrodes 120P may be formed on the first, second, third, and fourth fin-shaped patterns FMS1, FMS2, FMS3, and FMS4.

The dummy gate electrodes 120P may be formed on the first lower channel separation structures CCW_L1. The dummy gate electrodes 120P may each extend in the second direction DR2. The dummy gate electrodes 120P may be spaced apart from each other in the first direction DR1.

The dummy gate electrodes 120P may intersect the first, second, third, and fourth fin-shaped patterns FMS1, FMS2, FMS3, and FMS4. The dummy gate electrodes 120P may also intersect the first lower channel separation structures CCW_L.

For example, dummy gate insulating films 130P may be formed on the first, second, third, and fourth fin-shaped patterns FMS1, FMS2, FMS3, and FMS4. The dummy gate insulating films 130P may be formed along the profiles of the first, second, third, and fourth fin-shaped patterns FMS1, FMS2, FMS3, and FMS4 that protrude beyond the field insulating film 105. The dummy gate insulating films 130P may also be formed along the profiles of the lower channel separation structures CCW_L that protrude beyond the first, second, third, and fourth upper pattern structures UP1, UP2, UP3, and UP4.

The dummy gate electrodes 120P may be formed on the dummy gate insulating films 130P. Using dummy gate capping films 120HM as a mask, the dummy gate electrodes 120P and the dummy gate insulating films 130P may be formed. During the formation of the dummy gate electrodes 120P and the dummy gate insulating films 130P, portions of the lower channel separation structures CCW_L that do not overlap the dummy gate electrodes 120P in the third direction DR3 may be etched, thereby forming the first lower channel separation structures CCW_L1.

The dummy gate electrodes 120P may include, for example, polysilicon, but are not limited thereto. The dummy gate insulating films 130P may include, for example, silicon oxide, but are not limited thereto. The dummy gate capping films 120HM may include, for example, silicon nitride, but are not limited thereto.

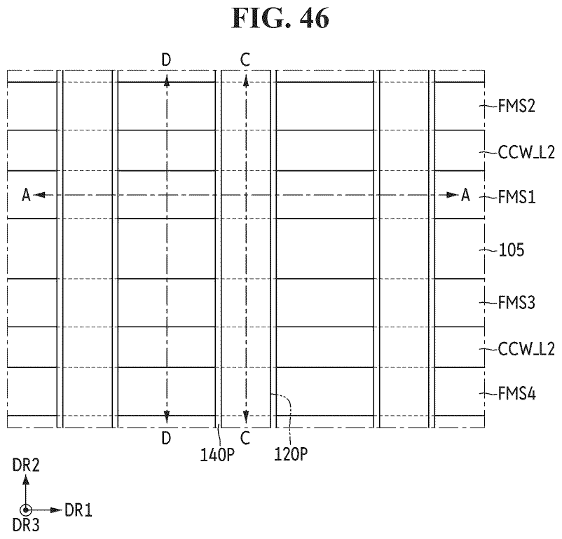

Referring to FIGS. 46 through 48, dummy gate spacers 140P may be formed on the sidewalls of the dummy gate electrodes 120P.

During the formation of the dummy gate spacers 140P, first source/drain recesses 150R, second source/drain recesses 250R, third source/drain recesses 350R, and fourth source/drain recesses 450R may be formed between the dummy gate electrodes 120P using the dummy gate electrodes 120P as a mask.

The first source/drain recesses 150R may be formed within the first mold fin-shaped pattern FMS1. The second source/drain recesses 250R may be formed within the second mold fin-shaped pattern FMS2. The third source/drain recesses 350R may be formed within the third mold fin-shaped pattern FMS3. The fourth source/drain recesses 450R may be formed within the fourth mold fin-shaped pattern FMS4.

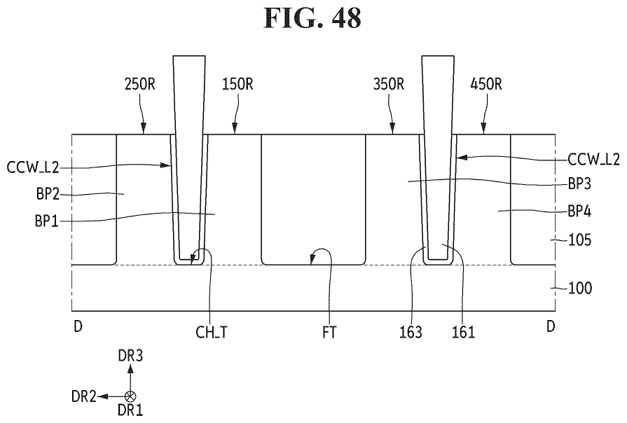

During the formation of the first source/drain recesses 150R, the second source/drain recesses 250R, the third source/drain recesses 350R, and the fourth source/drain recesses 450R, second lower channel separation structures CCW_L2 may be formed by removing portions of the first lower channel separation structures CCW_L1 exposed between adjacent dummy gate electrodes 120P. Referring to FIG. 48, portions of the liner separation patterns 163 formed on the sidewalls of the first core separation patterns 161 may be removed during the formation of the first source/drain recesses 150R, the second source/drain recesses 250R, the third source/drain recesses 350R, and the fourth source/drain recesses 450R.

Portions of the first lower channel separation structures CCW_L1 that overlap the dummy gate electrodes 120P in the third direction DR3 may not be etched. For example, from a cross-sectional perspective such as that illustrated in FIG. 48, the upper surfaces of the second lower channel separation structures CCW_L2 may be lower than the upper surfaces of the uppermost active patterns ACL_L.

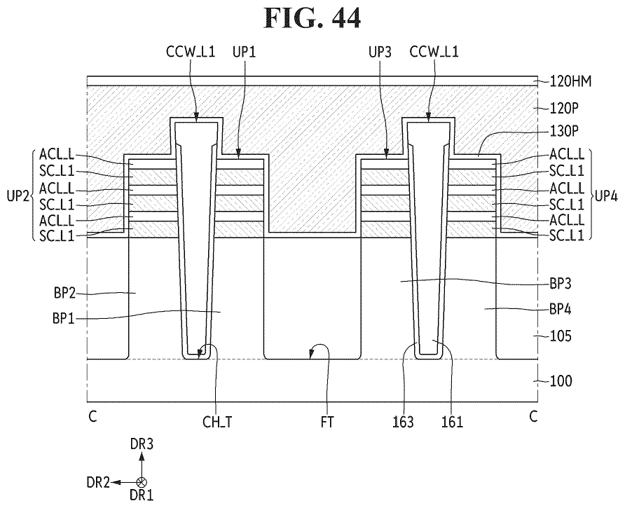

The cross-sectional view taken along line C-C of FIG. 46 may be substantially the same as that illustrated in FIG. 44 except for the presence of the second lower channel separation structures CCW_L2 in place of the first lower channel separation structures CCW_L1.

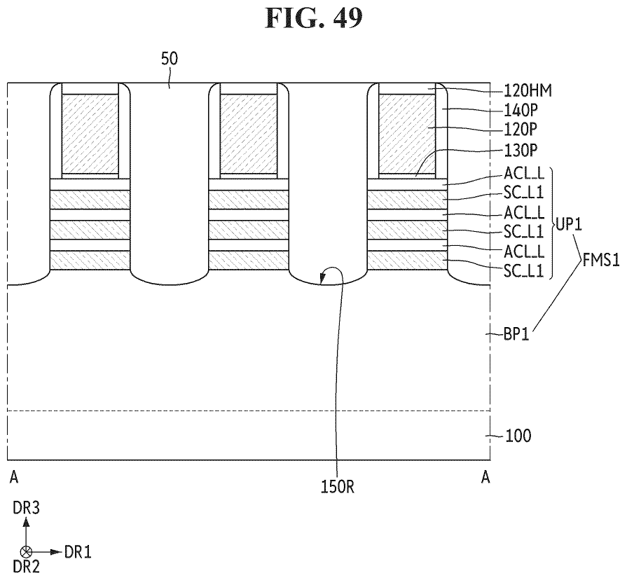

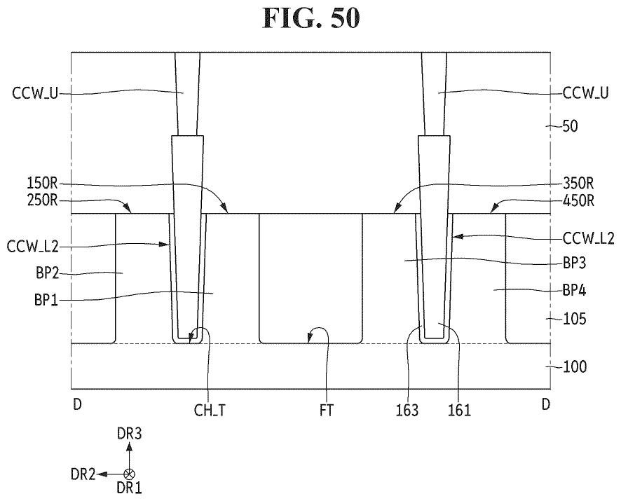

Referring to FIGS. 49 and 50, a sacrificial insulating film 50 may be formed on the first substrate 100.

The sacrificial insulating film 50 may fill the first source/drain recesses 150R, the second source/drain recesses 250R, the third source/drain recesses 350R, and the fourth source/drain recesses 450R. The sacrificial insulating film 50 may fill the spaces between the dummy gate electrodes 120P. The sacrificial insulating film 50 may be formed up to the upper surfaces of the dummy gate capping films 120HM.

Thereafter, upper channel separation structures CCW_U may be formed on the second lower channel separation structures CCW_L2. The upper channel separation structures CCW_U may be formed between adjacent dummy gate electrodes 120P in the first direction DR1. The upper channel separation structures CCW_U may be formed after forming the first source/drain recesses 150R, the second source/drain recesses 250R, the third source/drain recesses 350R, and the fourth source/drain recesses 450R.

The second core separation pattern 162 of FIG. 8 may be formed by one of the upper channel separation structures CCW_U.

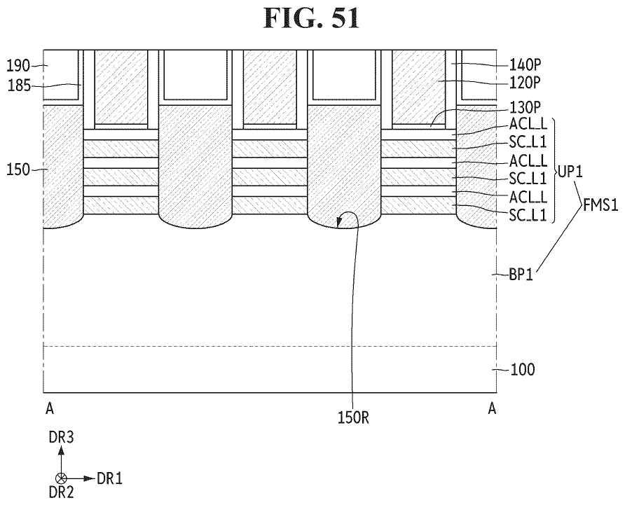

Referring to FIGS. 51 through 53, the sacrificial insulating film 50 may be removed.

As a result, the first source/drain recesses 150R, the second source/drain recesses 250R, the third source/drain recesses 350R, and the fourth source/drain recesses 450R may be exposed. For example, the first, second, third, and fourth upper pattern structures UP1, UP2, UP3, and UP4 may be exposed.

First source/drain patterns 150 may be formed within the first source/drain recesses 150R. The first source/drain patterns 150 may be formed on the first lower pattern BP1. Second source/drain patterns 250 may be formed within the second source/drain recesses 250R. The second source/drain patterns 250 may be formed on the second lower pattern BP2. Third source/drain patterns 350 may be formed within the third source/drain recesses 350R. The third source/drain patterns 350 may be formed on the third lower pattern BP3. Fourth source/drain patterns 450 may be formed within the fourth source/drain recesses 450R. The fourth source/drain patterns 450 may be formed on the fourth lower pattern BP4.

The first source/drain patterns 150, the second source/drain patterns 250, the third source/drain patterns 350, and the fourth source/drain patterns 450 may each be in contact with the upper channel separation structures CCW_U and the second lower channel separation structures CCW_L2.

Thereafter, a source/drain etching stop film 185 and an upper interlayer insulating film 190 may be formed on the source/drain patterns (150, 250, 350, and 450). During the formation of the source/drain etching stop film 185 and the upper interlayer insulating film 190, the dummy gate capping films 120HM may be removed, and the dummy gate electrodes 120P may be exposed.

Referring to FIGS. 51 through 55, the dummy gate electrodes 120P and the dummy gate insulating films 130P may be removed, thereby forming gate trenches 120t.

The gate trenches 120t may expose the first, second, third, and fourth upper pattern structures UP1, UP2, UP3, and UP4. The gate trenches 120t may extend in the second direction DR2.

Thereafter, the first sacrificial patterns SC_L1 of the first upper pattern structure UP1 exposed by the gate trenches 120t may be removed, thereby forming first sheet patterns NS1 in contact with the second lower channel separation structures CCW_L2 and the first source/drain patterns 150.

The first sacrificial patterns SC_L1 of the second upper pattern structure UP2 exposed by the gate trenches 120t may be removed, thereby forming second sheet patterns NS2 in contact with the second lower channel separation structures CCW_L2 and the second source/drain patterns 250.

The first sacrificial patterns SC_L1 of each of the third and fourth upper pattern structures UP3 and UP4 exposed by the gate trenches 120t may be removed, thereby forming third sheet patterns NS3 and fourth sheet patterns NS4. The third sheet patterns NS3 and the fourth sheet patterns NS4 may be in contact with the second lower channel separation structures CCW_L2.

During the removal of the first sacrificial patterns SC_L1 included in each of the first, second, third, and fourth upper pattern structures UP1, UP2, UP3, and UP4, portions of the liner separation patterns 163 included in the second lower channel separation structures CCW_L2 may be removed. The liner separation patterns 163 that do not overlap the first sheet patterns NS1, the second sheet patterns NS2, the third sheet patterns NS3, and the fourth sheet patterns NS4 in the second direction DR2 may be removed. As a result, a first channel separation pattern CCW1 and a second channel separation pattern CCW2 may be formed.

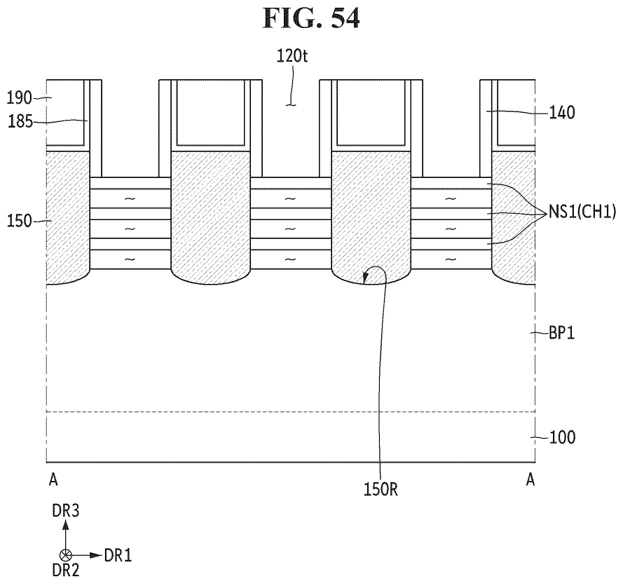

Referring to FIGS. 54 through 57, pre-gate electrodes 120PR and pre-gate insulating films 130PR may be formed within the gate trenches 120t.

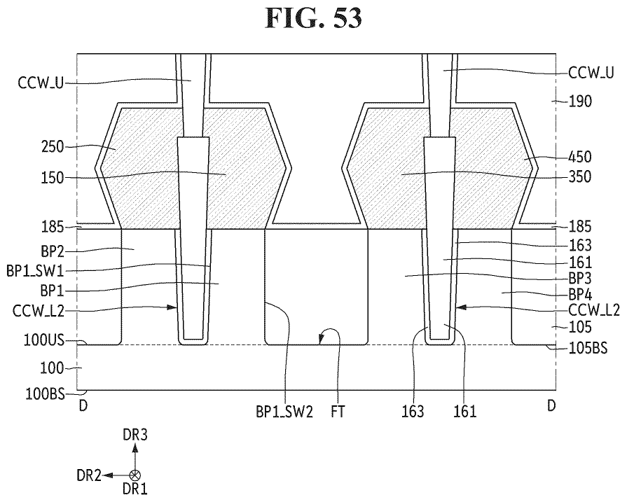

The pre-gate electrodes 120PR may intersect the first sheet patterns NS1, the second sheet patterns NS2, the third sheet patterns NS3, and the fourth sheet patterns NS4. The pre-gate electrodes 120PR may cover the upper surfaces of the first and second channel separation patterns CCW1 and CCW2. The upper surfaces of the pre-gate electrodes 120PR may be disposed on the same plane as the upper surfaces of the upper channel separation structures CCW_U illustrated in FIG. 53.

Referring to FIGS. 2 through 5, portions of the pre-gate electrodes 120PR and portions of the pre-gate insulating films 130PR may be removed, thereby forming first gate structures GS1, second gate structures GS2, third gate structures, and fourth gate structures GS4. The pre-gate electrodes 120PR and the pre-gate insulating films 130PR may be etched until the upper surfaces of the first and second channel separation patterns CCW1 and CCW2 are exposed. As a result, the first gate structures GS1, the second gate structures GS2, the third gate structures, and the fourth gate structures GS4 may be formed. First gate capping patterns 145 and second gate capping patterns 345 may be formed on the first gate structures GS1, the second gate structures GS2, the third gate structures, and the fourth gate structures GS4.

In some implementations, because of the presence of the channel separation structure during etching/material-removal operations in the foregoing process, the channel separation structure may protect underlying structure(s)/pattern(s) and prevent their etching. For example, the channel separation structure and/or portions thereof (e.g., being composed of silicon oxide) may be etched less than other structure(s) having etch selectivity with respect to the channel separation structure and/or portions thereof. Based on prevention of etching of the underlying structures, operation of the manufactured semiconductor devices may be improved.

Although operations are shown in a specific order in the drawings, it should not be understood that desired results can be obtained when the operations must be performed in the specific order or sequential order or when all of the operations must be performed. In certain situations, multitasking and parallel processing may be advantageous. Moreover, it should not be understood that the separation of various configurations is necessarily required, and it should be understood that the described program components and systems may generally be integrated together into a single software product or be packaged into multiple software products.

In concluding the detailed description, those skilled in the art will appreciate that many variations and modifications can be made to the above-described examples without departing from scope of the present disclosure.

What is claimed is:

1. A semiconductor device comprising:
a lower pattern including a first sidewall and a second sidewall that extend in a first direction and are spaced apart in a second direction;
a channel separation structure extending in the first direction, in contact with the first sidewall of the lower pattern, and including a core separation pattern and a liner separation pattern, wherein the liner separation pattern extends along a sidewall of the core separation pattern;
a field insulating film in contact with the second sidewall of the lower pattern;
a gate structure on the lower pattern, wherein the gate structure is in contact with the channel separation structure, and wherein the gate structure includes a gate electrode and a gate insulating film;
a channel pattern on the lower pattern, wherein the channel pattern includes a plurality of sheet patterns spaced apart in a third direction, wherein each sheet pattern of the plurality of sheet patterns is in contact with the channel separation structure; and
a source/drain pattern in contact with the channel pattern and the channel separation structure,
wherein
the core separation pattern includes a first portion, a second portion, and a connection portion,
the connection portion of the core separation pattern is between the first and second portions of the core separation pattern in the third direction,
the first portion of the core separation pattern overlaps the lower pattern along the second direction,
a slope of the sidewall of the core separation pattern at the connection portion is smaller than a slope of the sidewall of the core separation pattern at the first portion, and
the slope of the sidewall of the core separation pattern at the connection portion is smaller than a slope of the sidewall of the core separation pattern at the second portion.

2. The semiconductor device of claim 1, wherein the first portion of the core separation pattern overlaps the plurality of sheet patterns along the second direction.

3. The semiconductor device of claim 1, wherein:
the channel separation structure includes a first region in contact with the gate structure and a second region in contact with the source/drain pattern, wherein the first region and the second region are adjacent to one another along the first direction, and
the first region of the channel separation structure includes the first portion, the second portion, and the connection portion of the core separation pattern.

4. The semiconductor device of claim 1, wherein:
the core separation pattern includes an upper core separation pattern and a lower core separation pattern, and
the upper core separation pattern includes the connection portion and the second portion of the core separation pattern.

5. The semiconductor device of claim 1, wherein the liner separation pattern is between the plurality of sheet patterns and the core separation pattern and is in contact with the plurality of sheet patterns and the core separation pattern.

6. The semiconductor device of claim 5, wherein a thickness, in the third direction, of a portion of the liner separation pattern between (i) a first sheet pattern of the plurality of sheet patterns and (ii) the core separation pattern increases along the second direction away from the plurality of sheet patterns.

7. The semiconductor device of claim 5, wherein a thickness, in the third direction, of a portion of the liner separation pattern between (i) a first sheet pattern of the plurality of sheet patterns and (ii) the core separation pattern decreases and then increases along the second direction away from the plurality of sheet patterns.

8. The semiconductor device of claim 5, wherein a thickness, in the third direction, of a portion of the liner separation pattern between (i) a first sheet pattern of the plurality of sheet patterns and (ii) the core separation pattern is constant along the second direction away from the plurality of sheet patterns.

9. The semiconductor device of claim 1, wherein a width of the core separation pattern in the second direction increases along the third direction away from a bottom surface of the field insulating film in the first portion of the core separation pattern and in the second portion of the core separation pattern.

10. The semiconductor device of claim 1, wherein the gate structure and the source/drain pattern are in contact with the sidewall of the core separation pattern.

11. The semiconductor device of claim 1, wherein a thickness, along the second direction, of a portion of the liner separation pattern between (i) the plurality of sheet patterns and (ii) the core separation pattern is greater than a thickness of a portion of the liner separation pattern between (i) the source/drain pattern and (ii) the core separation pattern.

12. The semiconductor device of claim 1, further comprising:
a gate capping pattern on the gate structure and the channel separation structure,
wherein the channel separation structure is in contact with the gate capping pattern.

13. A semiconductor device comprising:
a lower pattern including a first sidewall and a second sidewall that extend in a first direction and are spaced apart in a second direction;
a channel separation structure extending in the first direction, wherein the channel separation structure is in contact with the first sidewall of the lower pattern, and wherein the channel separation structure includes a first core separation pattern, a second core separation pattern, and a liner separation pattern,
wherein the liner separation pattern extends along a sidewall of the first core separation pattern, and wherein the second core separation pattern is on the first core separation pattern;
a field insulating film in contact with the second sidewall of the lower pattern;
a gate structure on the lower pattern, wherein the gate structure is in contact with the channel separation structure, and wherein the gate structure includes a gate electrode and a gate insulating film;
a gate capping pattern on the gate structure and the channel separation structure, wherein the gate capping pattern is in contact with an upper surface of the first core separation pattern, wherein an upper surface of the gate capping pattern is on a same plane as an upper surface of the second core separation pattern;
a channel pattern on the lower pattern, wherein the channel pattern includes a plurality of sheet patterns spaced apart in a third direction, wherein each sheet pattern of the plurality of sheet patterns is in contact with the channel separation structure; and
a source/drain pattern in contact with the channel pattern and the channel separation structure,
wherein
the channel separation structure includes a first region in contact with the gate structure and a second region in contact with the source/drain pattern,
the first core separation pattern is in both the first and second regions of the channel separation structure,
the second core separation pattern is in the second region of the channel separation structure, and
the first core separation pattern has a “T” shape in a cross-section in the first region of the channel separation structure.

14. The semiconductor device of claim 13, wherein
in the first region of the channel separation structure, the first core separation pattern includes a first portion, a second portion, and a connection portion,
the connection portion of the first core separation pattern is between the first and second portions of the first core separation pattern,
the second portion of the first core separation pattern is in contact with the gate capping pattern,
a slope of the sidewall of the first core separation pattern at the connection portion is smaller than a slope of the sidewall of the first core separation pattern at the first portion, and
the slope of the sidewall of the first core separation pattern at the connection portion is smaller than a slope of the sidewall of the first core separation pattern at the second portion.

15. The semiconductor device of claim 14, wherein
the first core separation pattern includes an upper core separation pattern and a lower core separation pattern, and
the upper core separation pattern includes the connection portion and the second portion of the first core separation pattern.

16. The semiconductor device of claim 13, wherein
a width of the second core separation pattern in the second direction increases along the third direction away from a bottom surface of the field insulating film, and
a width of the first core separation pattern in the second direction in the second region of the channel separation structure continuously increases along the third direction away from the bottom surface of the field insulating film, from a bottom surface of the first core separation pattern to a bottom surface of the second core separation pattern.

17. The semiconductor device of claim 13, wherein:
a width of the second core separation pattern in the second direction increases along the third direction away from a bottom surface of the field insulating film, and
a width of the first core separation pattern in the second direction in the second region of the channel separation structure increases and then decreases along the third direction away from the bottom surface of the field insulating film.

18. The semiconductor device of claim 13, wherein the gate insulating film and the source/drain pattern are in contact with the sidewall of the first core separation pattern.

19. A semiconductor device comprising:
a lower pattern including a first sidewall and a second sidewall that extend in a first direction and are spaced apart in a second direction;
a channel separation structure extending in the first direction, wherein the channel separation structure is in contact with the first sidewall of the lower pattern, and wherein the channel separation structure includes a core separation pattern and a liner separation pattern;
a field insulating film in contact with the second sidewall of the lower pattern;
a gate structure on the lower pattern, wherein the gate structure extends in the second direction, and wherein the gate structure includes a gate electrode and a gate insulating film, wherein the gate insulating film is in contact with the core separation pattern;
a channel pattern on the lower pattern, wherein the channel pattern includes a plurality of sheet patterns spaced apart in a third direction, wherein each sheet pattern of the plurality of sheet patterns is in contact with the channel separation structure; and
a source/drain pattern in contact with the channel pattern and a sidewall of the core separation pattern,
wherein
the liner separation pattern includes:
a lower liner separation pattern between the sidewall of the core separation pattern and the first sidewall of the lower pattern, and
a plurality of connection liner separation patterns spaced apart in the third direction from the lower liner separation pattern,
wherein the plurality of connection liner separation patterns are between the plurality of sheet patterns and the core separation pattern,
the core separation pattern includes a first portion, a second portion, and a connection portion,
the connection portion of the core separation pattern is between the first portion and the second portion of the core separation pattern,
the lower liner separation pattern is between the first portion of the core separation pattern and the lower pattern,
a slope of the sidewall of the core separation pattern at the connection portion is smaller than a slope of the sidewall of the core separation pattern at the first portion, and
the slope of the sidewall of the core separation pattern at the connection portion is smaller than a slope of the sidewall of the core separation pattern at the second portion.

20. The semiconductor device of claim 19, wherein
the core separation pattern includes an upper core separation pattern and a lower core separation pattern, and
the upper core separation pattern includes the connection portion and the second portion of the core separation pattern.
